(19) United States
(12) Patent Application Publication
(10) Pub. No.: US 2024/0413179 A1
(43) Pub. Date: Dec. 12, 2024

(54) IMAGING DEVICE

(71) Applicant: SONY SEMICONDUCTOR SOLUTIONS CORPORATION, KANAGAWA (JP)

(72) Inventors: YUKA OHKUBO, KANAGAWA (JP); KAZUHIRO GOI, KANAGAWA (JP); TAICHI NATORI, KANAGAWA (JP); YUSUKE MORIYA, KANAGAWA (JP); SHINGO TAKAHASHI, KANAGAWA (JP); KEN YAHATA, KANAGAWA (JP); HIROSHI KATO, KANAGAWA (JP)

(21) Appl. No.: 18/701,191

(22) PCT Filed: Oct. 13, 2022
(86) PCT No.: PCT/JP2022/038276

§ 371 Date: Apr. 12, 2024

(30) Foreign Application Priority Data
Oct. 20, 2021 (JP) 2021-171661

(51) Int. Cl. H01L 27/146; G02B 19/00

(52) U.S. Cl. CPC H01L 27/14621; G02B 19/0009; G02B 19/0076; H01L 27/14623; H01L 27/14627; H01L 27/1463; H01L 27/14645; H01L 27/14685

(57) ABSTRACT

An imaging device according to an embodiment of the present disclosure includes: a semiconductor substrate having a first surface and a second surface opposed to each other, the semiconductor substrate including a plurality of pixels disposed in a matrix, and a plurality of photoelectric converters that each generates, through photoelectric conversion, electric charge corresponding to an amount of received light for each of the pixels; a plurality of color filters provided on a side of the first surface in respective ones of the plurality of pixels; a plurality of condensing lenses provided on a light incident side of the plurality of color filters in the respective ones of the plurality of pixels; and a separation wall provided between the plurality of color filters adjacent to each other on the side of the first surface, the separation wall having a line width on the light incident side narrower than the line width of the separation wall on the side of the first surface.

### TECHNICAL FIELD

The present disclosure relates to an imaging device including, for example, color filters and on-chip lenses.

### BACKGROUND ART

For example, PTL 1 discloses an image sensor in which a color filter array provided on a plurality of unit pixels is separated by a fence pattern between the adjacent unit pixels.

### CITATION LIST

### Patent Literature

PTL1: U.S. Patent Application Publication No. 2020/0083268

### SUMMARY OF THE INVENTION

Incidentally, an imaging device including color filters and on-chip lenses is desired to improve quantum efficiency and reduce occurrence of color mixing.

It is desirable to provide an imaging device that makes it possible to improve quantum efficiency and reduce occurrence of color mixing.

An imaging device according to an embodiment of the present disclosure includes: a semiconductor substrate having a first surface and a second surface opposed to each other, the semiconductor substrate including a plurality of pixels disposed in a matrix, and a plurality of photoelectric converters that each generates, through photoelectric conversion, electric charge corresponding to an amount of received light for each of the pixels; a plurality of color filters provided on a side of the first surface in respective ones of the plurality of pixels; a plurality of condensing lenses provided on a light incident side of the plurality of color filters in the respective ones of the plurality of pixels; and a separation wall provided between the plurality of color filters adjacent to each other on the side of the first surface, the separation wall having a line width on the light incident side narrower than the line width of the separation wall on the side of the first surface.

In the imaging device according to the embodiment of the present disclosure, the plurality of color filters and the plurality of condensing lenses are stacked in this order on the side of the first surface of the semiconductor substrate in the respective ones of the plurality of pixels, the semiconductor substrate having the first surface and the second surface opposed to each other. Further, the separation wall whose line width on the light incident side is narrower than the line width of the separation wall on the side of the first surface is provided between the plurality of pixels adjacent to each other. This reduces penetration of light reflected and scattered by the separation wall into the adjacent pixels.

### BRIEF DESCRIPTION OF DRAWINGS

FIG. 1 is a schematic cross-sectional view of an example of a configuration of an imaging device according to a first embodiment of the present disclosure.

FIG. 2 is a block diagram illustrating an overall configuration of the imaging device illustrated in FIG. 1.

FIG. 3 is an equivalent circuit diagram of a unit pixel illustrated in FIG. 1.

FIG. 4A is a schematic plan view of an example of the configuration of the imaging device and a layout of a separation wall illustrated in FIG. 1.

FIG. 4B is a schematic plan view of another example of the configuration of the imaging device and the layout of the separation wall illustrated in FIG. 1.

FIG. 4C is a schematic plan view of another example of the configuration of the imaging device and the layout of the separation wall illustrated in FIG. 1.

FIG. 5A is a schematic cross-sectional view of another example of a shape of the separation wall illustrated in FIG. 1.

FIG. 5B is a schematic cross-sectional view of another example of the shape of the separation wall illustrated in FIG. 1.

FIG. 5C is a schematic cross-sectional view of another example of the shape of the separation wall illustrated in FIG. 1.

FIG. 5D is a schematic cross-sectional view of another example of the shape of the separation wall illustrated in FIG. 1.

FIG. 5E is a schematic cross-sectional view of another example of the shape of the separation wall illustrated in FIG. 1.

FIG. 5F is a schematic cross-sectional view of another example of the shape of the separation wall illustrated in FIG. 1.

FIG. 5G is a schematic cross-sectional view of another example of the shape of the separation wall illustrated in FIG. 1.

FIG. 5H is a schematic cross-sectional view of another example of the shape of the separation wall illustrated in FIG. 1.

FIG. 5I is a schematic cross-sectional view of another example of the shape of the separation wall illustrated in FIG. 1.

FIG. 6 is a schematic cross-sectional view of another example of a configuration of the separation wall illustrated in FIG. 1.

FIG. 7A is a schematic cross-sectional view for describing an example of a manufacturing method of the separation wall illustrated in FIG. 1.

FIG. 7B is a schematic cross-sectional view of a step subsequent to FIG. 7A.

FIG. 7C is a schematic cross-sectional view of a step subsequent to FIG. 7B.

FIG. 7D is a schematic cross-sectional view of a step subsequent to FIG. 7C.

FIG. 7E is a schematic cross-sectional view of a step subsequent to FIG. 7D.

FIG. 7F is a schematic cross-sectional view of a step subsequent to FIG. 7E.

FIG. 7G is a schematic cross-sectional view of a step subsequent to FIG. 7F.

FIG. 8A is a schematic cross-sectional view for describing another example of the manufacturing method of the separation wall illustrated in FIG. 1.

FIG. 8B is a schematic cross-sectional view of a step subsequent to FIG. 8A.

FIG. 8C is a schematic cross-sectional view of a step subsequent to FIG. 8B.

FIG. 9A is a schematic cross-sectional view for describing another example of the manufacturing method of the separation wall illustrated in FIG. 5E.

FIG. 9B is a schematic cross-sectional view of a step subsequent to FIG. 9A.

FIG. 9C is a schematic cross-sectional view of a step subsequent to FIG. 9B.

FIG. 9D is a schematic cross-sectional view of a step subsequent to FIG. 9C.

FIG. 9E is a schematic cross-sectional view of a step subsequent to FIG. 9D.

FIG. 10A is a schematic cross-sectional view for describing another example of the manufacturing method of the separation wall illustrated in FIG. 1.

FIG. 10B is a schematic cross-sectional view of a step subsequent to FIG. 10A.

FIG. 10C is a schematic cross-sectional view of a step subsequent to FIG. 10B.

FIG. 10D is a schematic cross-sectional view of a step subsequent to FIG. 10C.

FIG. 11 is a schematic cross-sectional view of an example of a configuration of an imaging device according to Modification Example 1 of the present disclosure.

FIG. 12 is a schematic plan view for describing the configuration of the imaging device and a shape of a separation wall illustrated in FIG. 11.

FIG. 13A is a schematic view of an example of a cross-sectional configuration of the imaging device taken along a line I-I illustrated in FIG. 12.

FIG. 13B is a schematic view of an example of a cross-sectional configuration of the imaging device taken along a line II-II illustrated in FIG. 12.

FIG. 14A is a schematic view of another example of the cross-sectional configuration of the imaging device taken along the line I-I illustrated in FIG. 12.

FIG. 14B is a schematic view of another example of the cross-sectional configuration of the imaging device taken along the line II-II illustrated in FIG. 12.

FIG. 14C is a schematic view of another example of the cross-sectional configuration of the imaging device taken along a line III-III illustrated in FIG. 12.

FIG. 14D is a schematic view of another example of the cross-sectional configuration of the imaging device taken along a line IV-IV illustrated in FIG. 12.

FIG. 15 is a schematic cross-sectional view of another example of the configuration of the imaging device according to Modification Example 1 of the present disclosure.

FIG. 16A is a schematic cross-sectional view for describing another example of a manufacturing method of the separation wall illustrated in FIG. 11.

FIG. 16B is a schematic cross-sectional view of a step subsequent to FIG. 16A.

FIG. 16C is a schematic cross-sectional view of a step subsequent to FIG. 16B.

FIG. 17 is a schematic cross-sectional view of an example of a configuration of an imaging device according to Modification Example 2 of the present disclosure.

FIG. 18 is a schematic cross-sectional view of another example of the configuration of the imaging device according to Modification Example 2 of the present disclosure.

FIG. 19 is a schematic cross-sectional view of an example of a configuration of an imaging device according to Modification Example 3 of the present disclosure.

FIG. 20 is a schematic cross-sectional view of another example of the configuration of the imaging device according to Modification Example 3 of the present disclosure.

FIG. 21 is a schematic cross-sectional view of an example of a configuration of an imaging device according to Modification Example 4 of the present disclosure.

FIG. 22 is a schematic cross-sectional view of another example of the configuration of the imaging device according to Modification Example 4 of the present disclosure.

FIG. 23 is a schematic cross-sectional view of an example of a configuration of an imaging device according to a second embodiment of the present disclosure.

FIG. 24 is a schematic cross-sectional view of another example of the configuration of the imaging device according to the second embodiment of the present disclosure.

FIG. 25 is a schematic cross-sectional view of another example of the configuration of the imaging device according to the second embodiment of the present disclosure.

FIG. 26 is a schematic cross-sectional view of another example of the configuration of the imaging device according to the second embodiment of the present disclosure.

FIG. 27 is a schematic cross-sectional view of another example of the configuration of the imaging device according to the second embodiment of the present disclosure.

FIG. 28 is a schematic cross-sectional view of another example of the configuration of the imaging device according to the second embodiment of the present disclosure.

FIG. 29 is a schematic cross-sectional view of an example of a configuration of an imaging device according to Modification Example 5 of the present disclosure.

FIG. 30A is a schematic cross-sectional view for describing an example of a manufacturing method of a separation wall illustrated in FIG. 29.

FIG. 30B is a schematic cross-sectional view of a step subsequent to FIG. 30A.

FIG. 30C is a schematic cross-sectional view of a step subsequent to FIG. 30B.

FIG. 30D is a schematic cross-sectional view of a step subsequent to FIG. 30C.

FIG. 30E is a schematic cross-sectional view of a step subsequent to FIG. 30D.

FIG. 30F is a schematic cross-sectional view of a step subsequent to FIG. 30E.

FIG. 30G is a schematic cross-sectional view of a step subsequent to FIG. 30F.

FIG. 31 is a schematic cross-sectional view of another example of the configuration of the imaging device according to Modification Example 5 of the present disclosure.

FIG. 32 is a schematic cross-sectional view of another example of the configuration of the imaging device according to Modification Example 5 of the present disclosure.

FIG. 33 is a schematic cross-sectional view of an example of a configuration of an imaging device according to Modification Example 6 of the present disclosure.

FIG. 34A is a schematic cross-sectional view for describing an example of a manufacturing method of a separation wall illustrated in FIG. 33.

FIG. 34B is a schematic cross-sectional view of a step subsequent to FIG. 34A.

FIG. 34C is a schematic cross-sectional view of a step subsequent to FIG. 34B.

FIG. 34D is a schematic cross-sectional view of a step subsequent to FIG. 34C.

FIG. 34E is a schematic cross-sectional view of a step subsequent to FIG. 34D.

FIG. 35 is a schematic cross-sectional view of an example of a configuration of an imaging device according to Modification Example 7 of the present disclosure.

FIG. 36A is a schematic cross-sectional view of another example of a shape of a second wall of the imaging device illustrated in FIG. 35.

FIG. 36B is a schematic cross-sectional view of another example of the shape of the second wall of the imaging device illustrated in FIG. 35.

FIG. 37A is a schematic cross-sectional view of another example of the shape of the second wall of the imaging device illustrated in FIG. 35.

FIG. 37B is a schematic cross-sectional view of another example of the shape of the second wall of the imaging device illustrated in FIG. 35.

FIG. 38A is a schematic cross-sectional view for describing an example of a manufacturing method of a separation wall illustrated in FIG. 35.

FIG. 38B is a schematic cross-sectional view of a step subsequent to FIG. 38A.

FIG. 38C is a schematic cross-sectional view of a step subsequent to FIG. 38B.

FIG. 39A is a schematic cross-sectional view for describing another example of the manufacturing method of the separation wall illustrated in FIG. 35.

FIG. 39B is a schematic cross-sectional view of a step subsequent to FIG. 39A.

FIG. 40 is a schematic cross-sectional view of an example of a configuration of an imaging device according to Modification Example 8 of the present disclosure.

FIG. 41 is a block diagram illustrating a configuration example of an electronic apparatus including the imaging device illustrated in FIG. 1.

FIG. 42A is a schematic view of an example of an overall configuration of a photodetection system using the imaging device illustrated in FIG. 1 and the like.

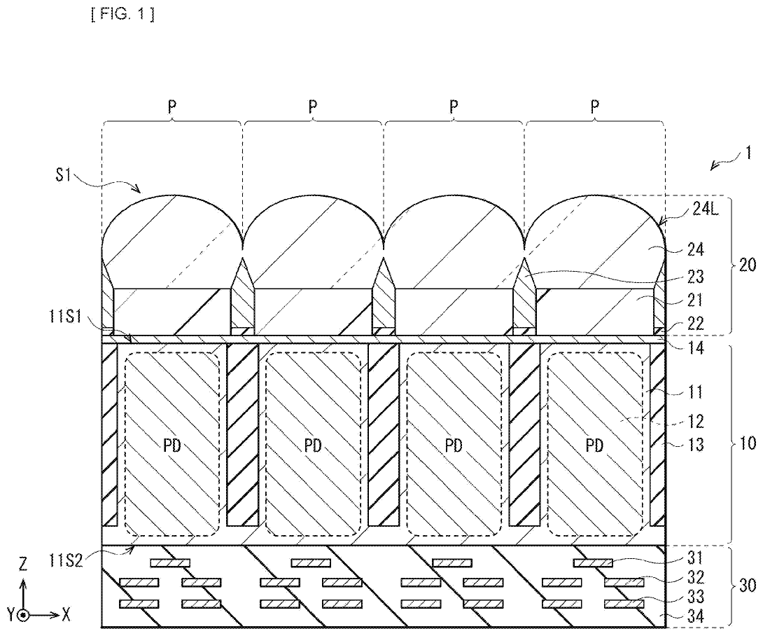

FIG. 1 is a diagram illustrating an example of a circuit configuration of the photodetection system illustrated in FIG. 42A.

FIG. 43 is a block diagram depicting an example of schematic configuration of a vehicle control system.

FIG. 44 is a diagram of assistance in explaining an example of installation positions of an outside-vehicle information detecting section and an imaging section.

FIG. 45 is a view depicting an example of a schematic configuration of an endoscopic surgery system.

FIG. 46 is a block diagram depicting an example of a functional configuration of a camera head and a camera control unit (CCU).

### MODES FOR CARRYING OUT THE INVENTION

Hereinafter, a detailed description is given of embodiments of the present disclosure with reference to the drawings. The following description is merely a specific example of the present disclosure, and the present disclosure is not limited to the following embodiments. Further, the present disclosure is not limited to arrangements, dimensions, dimensional ratios, and the like of each of components illustrated in the drawings. It is to be noted that the description is given in the following order.
1. First Embodiment (An example of an imaging device including, between adjacent color filters, a separation wall whose line width on a light incident side is narrower than a line width thereof on a side of a semiconductor substrate)
2. Modification Examples
   2-1. Modification Example 1 (Another example of the separation wall)
   2-2. Modification Example 2 (An example in which a light-blocking section is omitted)
   2-3. Modification Example 3 (Another example of the separation wall)
   2-4. Modification Example 4 (An example in which a first surface of a semiconductor substrate has an uneven shape)
3. Second Embodiment (An example of an imaging device that performs pupil correction using the light-blocking section, and the line width and a height of the separation wall)
4. Modification Examples
   4-1. Modification Example 5 (An example in which a first wall is formed by an air gap and a second wall includes a low refractive index material)
   4-2. Modification Example 6 (An example in which both the first wall and the second wall are formed by an air gap)
   4-3. Modification Example 7 (An example in which the second wall is formed from surfaces of on-chip lenses)
   4-4. Modification Example 8 (An example in which the light-blocking section is used as the separation wall)
5. Application Examples
6. Practical Application Examples

### 1. FIRST EMBODIMENT

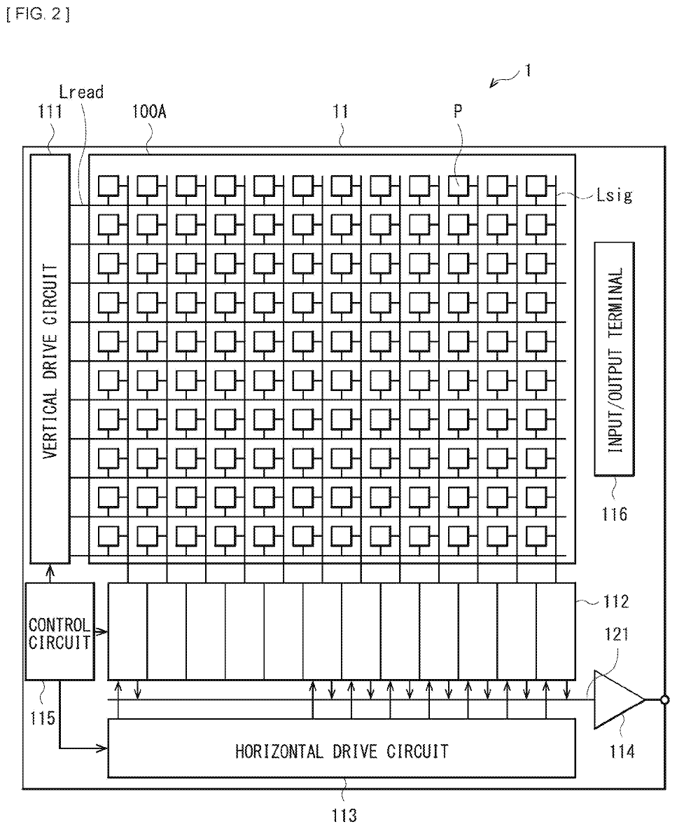

FIG. 1 schematically illustrates an example of a cross-sectional configuration of an imaging device (an imaging device 1) according to a first embodiment of the present disclosure. FIG. 2 illustrates an example of an overall configuration of the imaging device 1 illustrated in FIG. 1. The imaging device 1 is, for example, a CMOS (Complementary Metal Oxide Semiconductor) image sensor to be used for an electronic apparatus such as a digital still camera or a video camera, and includes, as an imaging area, a pixel section (a pixel section 100A) in which a plurality of pixels is disposed two-dimensionally in a matrix. The imaging device 1 is, for example, a so-called back-illuminated imaging device in the CMOS image sensor, or the like.

In the imaging device 1, for example, a plurality of color filters 21 and a plurality of on-chip lenses 24L are stacked in respective ones of a plurality of unit pixels P disposed in a matrix. A separation wall 23 is provided between the plurality of color filters 21 adjacent to each other. A line width of the separation wall 23 on a light incident side S1 is narrower than the line width thereof on a side of a first surface 11S1 of a semiconductor substrate 11.

### [Schematic Configuration of Imaging Device]

The imaging device 1 takes in incident light (image light) from a subject through an optical lens system (for example, a lens group 1001, see FIG. 29). The imaging device 1 converts a light amount of the incident light, an image of which is formed on an imaging plane, into an electric signal on a pixel-by-pixel basis, and outputs the electric signal as a pixel signal. The imaging device 1 includes the pixel section 100A serving as the imaging area on the semiconductor substrate 11, and includes, for example, a vertical drive circuit 111, column signal processing circuits 112, a horizontal drive circuit 113, an output circuit 114, a control circuit 115, and an input/output terminal 116 in a peripheral region of this pixel section 100A.

The pixel section 100A includes, for example, the plurality of unit pixels P disposed two-dimensionally in a matrix. The plurality of unit pixels P each photoelectrically converts, in a photodiode PD, a subject image formed by an imaging lens to generate a signal for image generation.

For example, the unit pixels P are wired with pixel drive lines Lread (specifically, row selection lines and reset control lines) for respective pixel rows, and are wired with vertical signal lines Lsig for respective pixel columns. The pixel drive lines Lread transmit drive signals for reading signals from the pixels. One end of each of the pixel drive lines Lread is coupled to an output end corresponding to the respective row of the vertical drive circuit 111.

The vertical drive circuit 111 includes a shift register, an address decoder, and the like, and is a pixel driver that drives the respective unit pixels P of the pixel section 100A, for example, on a row-by-row basis. The signals outputted from the respective unit pixels P in the pixel rows selectively scanned by the vertical drive circuit 111 are supplied to the column signal processing circuits 112 through the respective vertical signal lines Lsig. The column signal processing circuits 112 each include an amplifier, a horizontal selection switch, and the like provided for each of the vertical signal lines Lsig.

The horizontal drive circuit 113 includes a shift register, an address decoder, and the like, and sequentially drives the respective horizontal selection switches of the column signal processing circuits 112 while scanning the horizontal selection switches. This selective scanning by the horizontal drive circuit 113 allows the signals of the respective pixels transmitted through the respective vertical signal lines Lsig to be sequentially outputted to a horizontal signal line 121 and transmitted to the outside of the semiconductor substrate 11 through the horizontal signal line 121.

The output circuit 114 performs signal processing on the signals sequentially supplied from the respective column signal processing circuits 112 through the horizontal signal line 121 and outputs the obtained signals. The output circuit 114 performs, for example, only buffering in some cases and performs black level adjustment, column variation correction, and various kinds of digital signal processing in other cases.

Circuit portions including the vertical drive circuit 111, the column signal processing circuits 112, the horizontal drive circuit 113, the horizontal signal line 121, and the output circuit 114 may be formed directly on the semiconductor substrate 11 or may be provided in an external control IC. Alternatively, those circuit portions may be formed on any other substrate coupled by a cable or the like.

The control circuit 115 receives a clock given from the outside of the semiconductor substrate 11, data for an instruction about an operation mode, and the like, and also outputs data such as internal information regarding the imaging device 1. The control circuit 115 further includes a timing generator that generates various timing signals, and performs drive control of a peripheral circuit such as the vertical drive circuit 111, the column signal processing circuits 112, or the horizontal drive circuit 113 on the basis of the various timing signals generated by the timing generator.

The input/output terminal 116 exchanges signals with the outside.

### [Circuit Configuration of Unit Pixel]

FIG. 3 illustrates an example of a readout circuit of the unit pixel P of the imaging device 1 illustrated in FIG. 2. The unit pixel P includes, for example, one photoelectric converter 12, a transfer transistor TR, a floating diffusion FD, a reset transistor RST, an amplification transistor AMP, and a selection transistor SEL, as illustrated in FIG. 3.

The photoelectric converter 12 is a photodiode (PD). The photoelectric converter 12 has an anode coupled to a ground voltage line, and a cathode coupled to a source of the transfer transistor TR1.

The transfer transistor TR1 is coupled between the photoelectric converter 12 and the floating diffusion FD. A drive signal TRsig is applied to a gate electrode of the transfer transistor TR. When this drive signal TRsig is brought into an active state, a transfer gate of the transfer transistor TR is brought into an electrically conductive state to transfer signal electric charge accumulated in the photoelectric converter 12 to the floating diffusion FD through the transfer transistor TR.

The floating diffusion FD is coupled between the transfer transistor TR and the amplification transistor AMP. The floating diffusion FD converts the signal electric charge transferred by the transfer transistor TR into a voltage signal through electric charge-voltage conversion, and outputs the voltage signal to the amplification transistor AMP.

The reset transistor RST is coupled between the floating diffusion FD and a power supply section. A drive signal RSTsig is applied to a gate electrode of the reset transistor RST. When the drive signal RSTsig is brought into the active state, a reset gate of the reset transistor RST is brought into the electrically conductive state to reset a potential of the floating diffusion FD to a level of the power supply section.

The amplification transistor AMP has a gate electrode coupled to the floating diffusion FD, and a drain electrode coupled to the power supply section, and serves as an input part of a readout circuit for the voltage signal held by the floating diffusion FD, i.e., a so-called source follower circuit. In other words, the amplification transistor AMP has a source electrode coupled to the vertical signal line Lsig through the selection transistor SEL, thereby configuring a source follower circuit with a constant current source coupled to one end of the vertical signal line Lsig.

The selection transistor SEL is coupled between the source electrode of the amplification transistor AMP and the vertical signal line Lsig. A drive signal SELsig is applied to a gate electrode of the selection transistor SEL. When the drive signal SELsig is brought into the active state, the selection transistor SEL is brought into the electrically conductive state to bring the unit pixel P into a selected state. This allows a readout signal (a pixel signal) outputted from the amplification transistor AMP to be outputted to the vertical signal line Lsig through the selection transistor SEL.

### [Configuration of Unit Pixel]

The imaging device 1 is, for example, a back-illuminated imaging device, as described above. The plurality of unit pixels P disposed two-dimensionally in a matrix in the pixel section 100A each has, for example, a configuration in which a light receiver 10, a light condenser 20, and a multilayer wiring layer 30 are stacked. The light condenser 20 is provided on the light incident side S1 of the light receiver 10. The multilayer wiring layer 30 is provided on a side opposite to the light incident side S1 of the light receiver 10.

The light receiver 10 includes the semiconductor substrate 11 and a plurality of photoelectric converters 12. The semiconductor substrate 11 has a first surface 11S1 and a second surface 11S2 opposed to each other. The plurality of photoelectric converters 12 is formed to be embedded in the semiconductor substrate 11. The semiconductor substrate 11 includes, for example, a silicon substrate. Each of the photoelectric converters 12 is, for example, a PIN (Positive Intrinsic Negative) photodiode (PD), and includes a pn junction in a predetermined region of the semiconductor substrate 11. As described above, the photoelectric converters 12 are formed to be embedded in the respective unit pixels P.

The light receiver 10 further includes an element separator 13.

The element separator 13 is provided between the adjacent unit pixels P. In other words, the element separator 13 is provided around each of the unit pixels P, and is provided in a lattice pattern in the pixel section 100A. The element separator 13 electrically and optically separates the adjacent unit pixels P from each other. The element separator 13 extends, for example, from the side of the first surface 11S1 toward a side of the second surface 11S2 of the semiconductor substrate 11. It is possible to form the element separator 13, for example, through diffusion of a p-type impurity. In addition thereto, the element separator 13 may have, for example, a STI (Shallow Trench Isolation) structure or a FFTI (Full Trench Isolation) structure in which an opening is formed in the semiconductor substrate 11 from the side of the first surface 11S1, and a side surface and a bottom surface of the opening are covered with a fixed electric charge layer 14 to embed an insulating layer therein. In addition, an air gap may be formed in the STI structure and the FFTI structure.

The fixed electric charge layer 14 is further provided on the first surface 11S1 of the semiconductor substrate 11. The fixed electric charge layer 14 also serves to prevent reflection at the first surface 11S1 of the semiconductor substrate 11. The fixed electric charge layer 14 may be a film including positive fixed electric charge or a film including negative fixed electric charge. Examples of a constituent material of the fixed electric charge layer 14 include a semiconductor material and an electrically conductive material having a band gap wider than a band gap of the semiconductor substrate 11. Specific examples thereof include hafnium oxide (HfOₓ), aluminum oxide (AlOₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOₓ), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), and aluminum oxynitride (AlOₓN_{y}). The fixed electric charge layer 14 may be a single-layer film, or may be a stacked film including different materials.

The light condenser 20 includes, for example, on the light incident side S1 of the light receiver 10, the plurality of color filters 21, a light-blocking section 22, and a lens layer 24 for the respective unit pixels P. The plurality of color filters 21 each selectively transmits, for example, red light (R), green light (G), or blue light (B). The light-blocking section 22 is provided between the respective unit pixels P of the plurality of color filters 21. The lens layer 24 is provided on the plurality of color filters 21. The light condenser 20 further includes the separation wall 23 provided between the adjacent color filters 21.

The color filters 21 each selectively transmit light having a predetermined wavelength. The color filters 21 are disposed, for example, in four unit pixels P disposed in two rows×two columns, with two color filters 21G that each selectively transmit the green light (G) being disposed on a diagonal line and with color filters 21R and 21B that selectively transmit the red light (R) and the blue light (B), respectively, being each disposed on a diagonal line orthogonal thereto. In the unit pixels P provided with the respective color filters 21R, 21G, and 21B, for example, corresponding color light beams are detected in the respective photoelectric converters 12. In other words, in the pixel section 100A, the unit pixels P that detect the red light (R), the unit pixels P that detect the green light (G), and the unit pixels P that detect the blue light (B) are disposed in a Bayer pattern.

The color filters 21 may include filters that each selectively transmit a corresponding one of cyan, magenta, or yellow. In the unit pixels P provided with the respective color filters 21R, 21G, and 21B, for example, corresponding color light beams are detected in the respective photoelectric converters 12. It is possible to form the color filters 21, for example, through dispersion of a pigment or a dye in a resin material. The color filters 21 may each have a film thickness that differs depending on a corresponding color in consideration of sensor sensitivity and color reproducibility by a spectral spectrum thereof.

The light-blocking section 22 prevents light obliquely incident on the color filter 21 from leaking into the adjacent unit pixels P, and is provided between the unit pixels P of the color filters 21, as described above. In other words, the light-blocking section 22 is provided in a lattice pattern above the element separator 13, for example, in the pixel section 100A.

It is to be noted that the light-blocking section 22 may also serve as light blocking for the unit pixels P that determines an optical black level. In addition, the light-blocking section 22 may also serve as light blocking for suppressing generation of noise to the peripheral circuits provided in the peripheral region of the pixel section 100A.

Examples of a material included in the light-blocking section 22 include an electrically conductive material having alight-blocking property. Specific examples thereof include tungsten (W), silver (Ag), copper (Cu), titanium (Ti), aluminum (Al), and alloys thereof. The examples further include a metal compound such as TiN. The light-blocking section 22 may be formed, for example, as a single-layer film or a stacked film. In a case where the light-blocking section 22 is formed as a stacked film, for example, a layer including Ti, tantalum (Ta), W, cobalt (Co), molybdenum (Mo), or an alloy thereof, a nitride thereof, an oxide thereof, or a carbide thereof may be provided as an underlayer.

The separation wall 23 prevents light obliquely incident from the light incident side S1 from leaking into the adjacent unit pixels P. The separation wall 23 is provided, for example, on the light-blocking section 22. In other words, the separation wall 23 is provided between the unit pixels P of the color filters 21, and is provided, for example, in a lattice pattern in the pixel section 100A, in a similar manner to the light-blocking section 22.

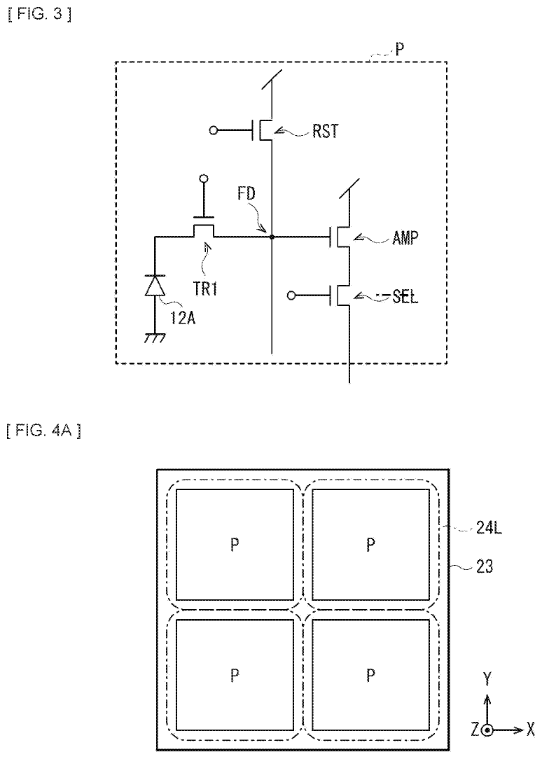

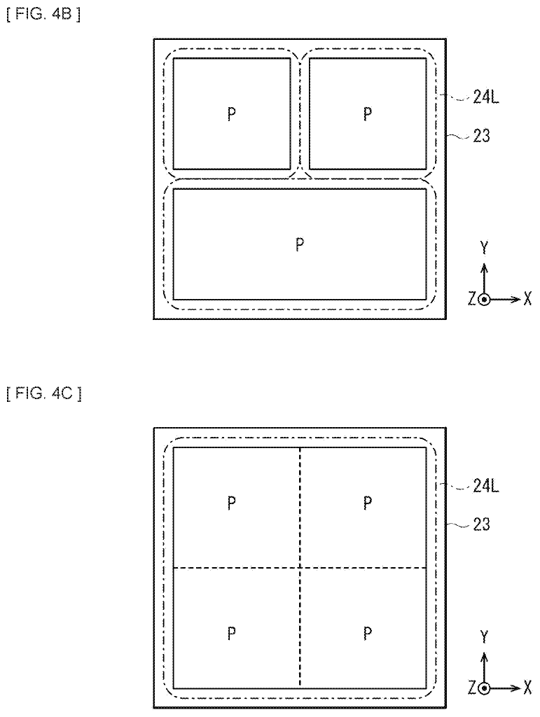

FIGS. 4A to 4C each schematically illustrate an example of a planar configuration of the imaging device 1 for describing a planar layout of the separation wall 23. In the imaging device 1, the plurality of on-chip lenses 24L is disposed one by one in the respective unit pixels P, as illustrated in FIG. 4A, for example. In such a configuration, the separation wall 23 is provided to surround each of the unit pixels P. In addition, in a case where the on-chip lens 24L is provided over the plurality of unit pixels P, the separation wall between the plurality of unit pixels P over which the on-chip lens 24L is provided is omitted, as illustrated in FIGS. 4B and 4C, for example. The plurality of unit pixels P over which the on-chip lens 24L is provided as illustrated in FIGS. 4B and 4C is provided with the color filter 21 of the same color. In other words, the separation wall 23 may be selectively provided only between the color filters 21 of different colors.

The separation wall 23 of the present embodiment, for example, penetrates the color filters 21 and protrudes into the lens layer 24. Specifically, the separation wall 23 includes a first wall 23A that penetrates the color filters 21 and a second wall 23B that protrudes into the lens layer 24. The first wall 23A is formed to have, for example, a constant line width in a Z-axis direction, and the second wall 23B has, for example, inclined surfaces that allow the separation wall 23 to have a line width that gradually narrows from the side of the first surface 11S1 of the semiconductor substrate 11 toward the light incident side S1, as illustrated in FIG. 1.

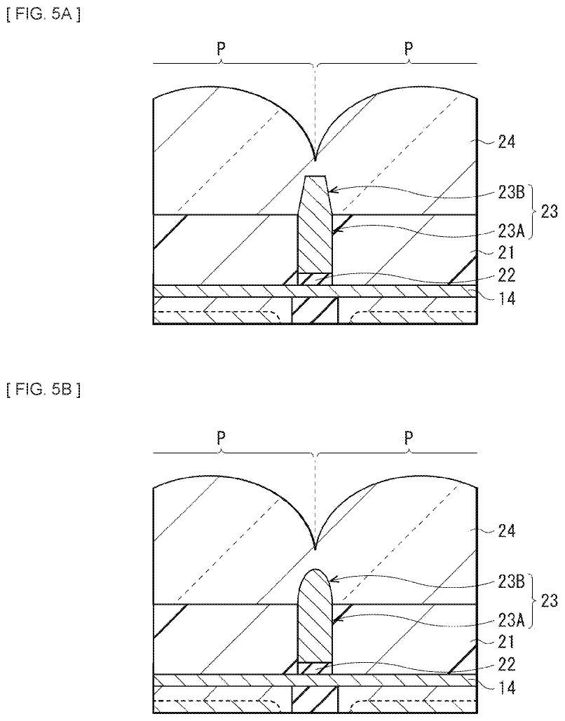

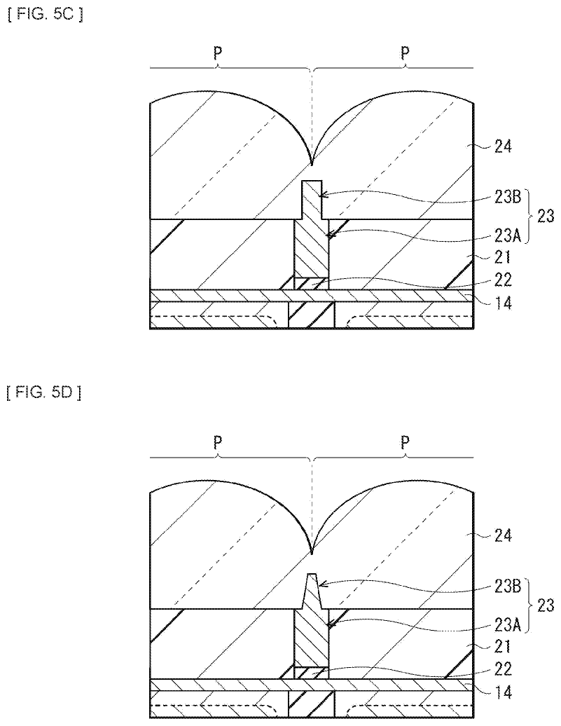

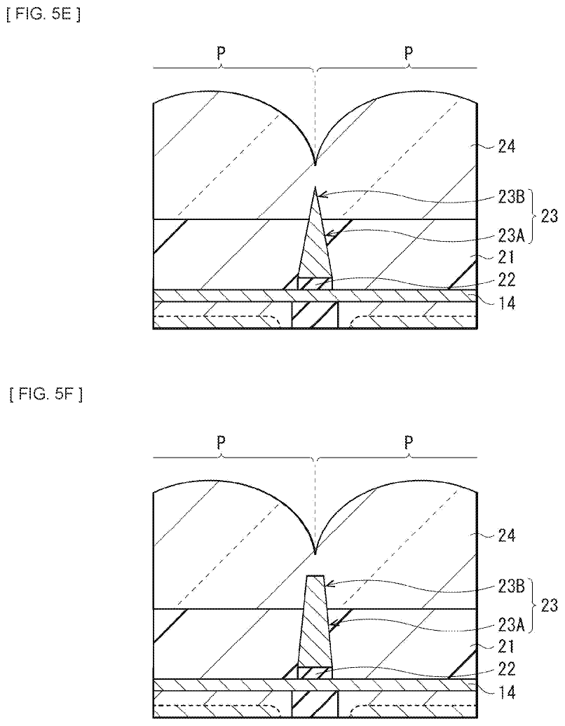

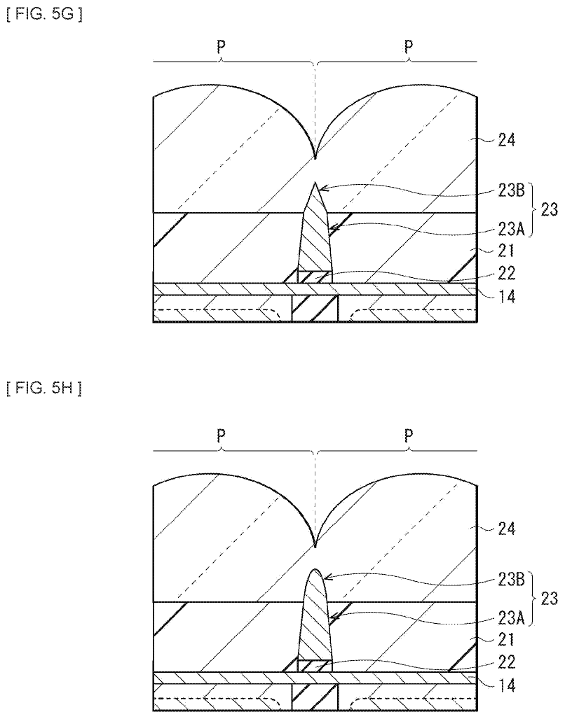

FIGS. 5A to 5I each schematically illustrate an example of a cross-sectional shape of the separation wall 23. FIG. 1 illustrates the example in which the first wall 23A that penetrates the color filters 21 has a rectangular cross-sectional shape, and the second wall 23B that protrudes into the lens layer 24 has a triangular cross-sectional shape; however, the present disclosure is not limited thereto. It is sufficient to configure the separation wall 23 in which at least the line width of the second wall 23B on the light incident side S1 is narrower than the line width of the first wall 23A. For example, the second wall 23B may have a trapezoidal cross-sectional shape, as illustrated in FIG. 5A. For example, the second wall 23B may have a substantially semicircular cross-sectional shape having a curved side surface, as illustrated in FIG. 5B. For example, the second wall 23B may have a substantially rectangular cross-sectional shape whose line width is narrower than that of the first wall 23A, as illustrated in FIG. 5C. For example, the second wall 23B may have a trapezoidal cross-sectional shape whose entire line width is narrower than the line width of the first wall 23A, as illustrated in FIG. 5D.

In addition, FIGS. 1 and 5A to 5G each illustrate the example in which the first wall 23A is formed to have a constant line width; however, the present disclosure is not limited thereto. The line width of the separation wall 23 may vary continuously or stepwise from the side of the first surface 11S1 toward the light incident side S1. For example, the separation wall 23 may have a triangular cross-sectional shape whose line width continuously narrows from the side of the first surface 11S1 of the semiconductor substrate 11 toward the light incident side S1, as illustrated in FIG. 5E. For example, the separation wall 23 may have a trapezoidal cross-sectional shape whose line width continuously narrows from the side of the first surface 11S1 of the semiconductor substrate 11 toward the light incident side S1, as illustrated in FIG. 5F. For example, the separation wall 23 may have a cross-sectional shape whose line width continuously narrows from the side of the first surface 11S1 of the semiconductor substrate 11 toward the light incident side S1 and that has, for example, an inflection point of an inclination angle at a boundary between the first wall 23A and the second wall 23B, as illustrated in FIG. 5G. For example, the separation wall 23 may have a cross-sectional shape whose line width continuously narrows from the side of the first surface 11S1 of the semiconductor substrate 11 toward the light incident side S1 and that has a substantially semicircular tip, as illustrated in FIG. 5H. In addition, for example, the separation wall 23 may have a substantially rectangular cross-sectional shape in which the line width of the first wall 23A continuously narrows from the side of the first surface 11S1 of the semiconductor substrate 11 toward the light incident side S1, and the line width of the second wall 23B is narrower than the line width of the first wall 23A, as illustrated in FIG. 5I.

It is possible for the separation wall 23 to include, for example, a material having a refractive index lower than that of the lens layer 24 to be described later or a metal material that absorbs incident light. Examples of the low refractive index material include a hollow silica-containing resin material and a porous material having a refractive index of 1.1 or more and 1.45 or less. Examples of the metal material include tungsten (W), titanium (Ti), titanium nitride (TiN), and aluminum (Al). In addition, the first wall 23A and the second wall 23B of the separation wall 23 may include materials different from each other. For example, the first wall 23A may include the above-described resin material or porous material having a low refractive index, and the second wall 23B may include the above-described metal material such as tungsten (W).

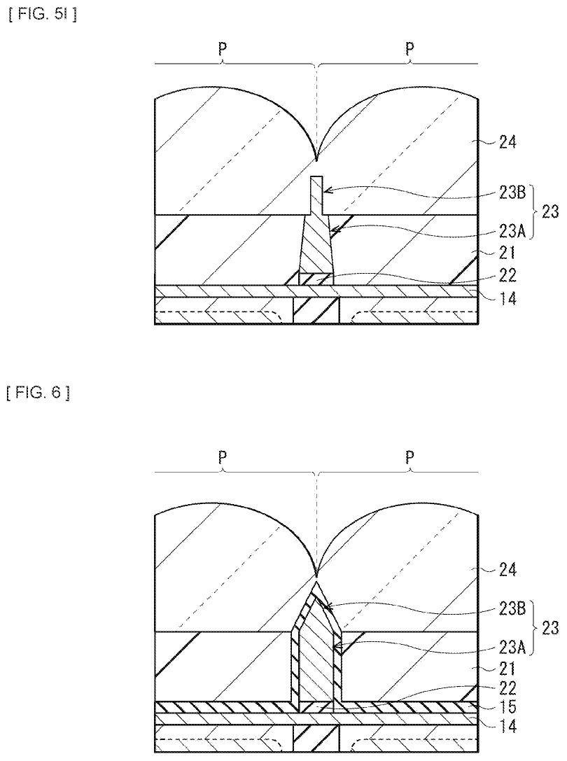

It is to be noted that a surface of the separation wall 23 may be covered with an insulating film 15, as illustrated in FIG. 6, for example. It is preferable that the insulating film 15 include, for example, a low refractive index material such as silicon oxide. For example, in a case where the separation wall 23 includes a porous material, covering the surface of the separation wall 23 with the insulating film 25 makes it possible to prevent the color filters 21 from penetrating into the separation wall 23.

The lens layer 24 is provided to cover an entire surface of the pixel section 100A. The lens layer 24 has, for example, a surface on which the plurality of on-chip lenses 24L is provided in a gapless manner. The on-chip lenses 24L each condense light incident from above into a corresponding one of the photoelectric converters 12. For example, the on-chip lenses 24L are provided in the respective unit pixels P, with the element separator 13 and the separation wall 23 substantially coinciding with a boundary between the plurality of on-chip lenses 24L in a plan view, as illustrated in FIG. 4. The lens layer 24 includes, for example, a resin material having a refractive index of 1.5 or more and 2.0 or less, a resin material having a refractive index of 1.5 or more and 2.0 or less, or an inorganic material such as silicon nitride (SiNₓ), silicon oxynitride (SiON), silicon oxide (SiOₓ), or amorphous silicon. In addition thereto, the lens layer 24 may include an organic material having a high refractive index such as an episulfide-based resin, a thiethane compound, or a resin thereof. A shape of each of the on-chip lenses 24L is not particularly limited, and various lens shapes such as a hemispherical shape or a semi-cylindrical shape are adoptable.

For example, the surface of the lens layer 24 may be provided with a protective film having a reflection prevention function. A film thickness of the protective film satisfies λ/4n, with respect to a wavelength λ to be detected and a refractive index n of the protective film.

The multilayer wiring layer 30 is provided on the side opposite to the light incident side S1 of the light receiver 10. Specifically, the multilayer wiring layer 30 is provided on the side of the second surface 11S2 of the semiconductor substrate 11. The multilayer wiring layer 30 has a configuration in which a plurality of wiring layers 31, 32, and 33 is stacked with an interlayer insulating layer 34 interposed therebetween. In addition to the readout circuit described above, for example, the vertical drive circuit 111, the column signal processing circuits 112, the horizontal drive circuit 113, the output circuit 114, the control circuit 115, and the input/output terminal 116 are formed on the multilayer wiring layer 30.

The wiring layers 31, 32, and 33 each include, for example, aluminum (Al), copper (Cu), or tungsten (W). The wiring layers 31, 32, and 33 may each include polysilicon (poly-Si) other than these materials.

The interlayer insulating layer 34 is formed, for example, by a single-layer film including one kind from among silicon oxide (SiOₓ), TEOS, silicon nitride (SiNₓ), silicon oxynitride (SiOₓN_{y}), and the like, or by a stacked film including two or more kinds from among these materials.

### [Manufacturing Method 1 of Separation Wall]

It is possible to form the separation wall 23 of the present embodiment, for example, as follows.

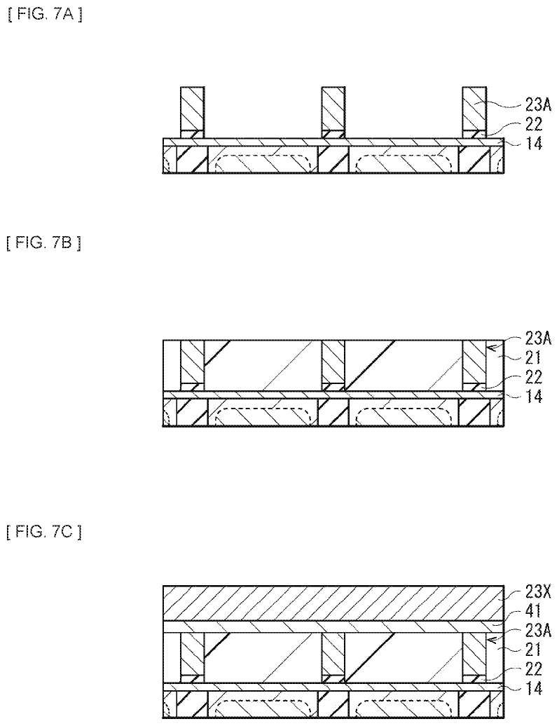

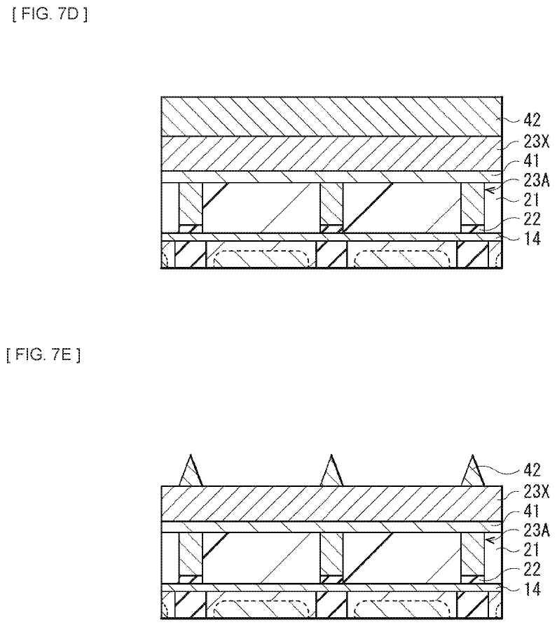

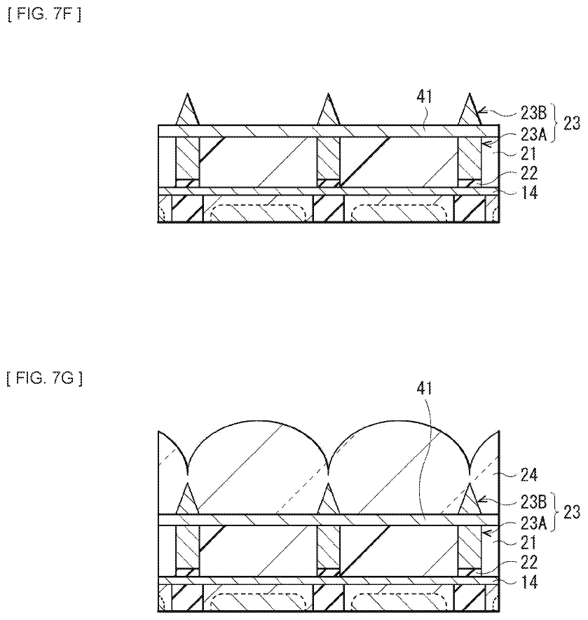

First, the fixed electric charge layer 14 is formed on the first surface 11S1 of the semiconductor substrate 11 using, for example, a chemical vapor deposition (CVD) method, sputtering, or an atomic layer deposition (ALD) method. Thereafter, the light-blocking section 22 is formed above the element separator 13 using, for example, a CVD method or sputtering, a photolithography technique, etching, and the like. Thereafter, for example, a low refractive index material is applied on the fixed electric charge layer 14 and the light-blocking section 22 at a predetermined thickness, following which the first wall 23A is formed on the light-blocking section 22 using a photolithography technique, etching, and the like, as illustrated in FIG. 7A.

Next, each of the color filters 21 is formed between the first walls 23A using a photolithography technique, as illustrated in FIG. 7B. Thereafter, a silicon nitride film 41 is formed, as an etching stopper film, on the color filters 21 and the first wall 23A, followed by further forming, on the silicon nitride film 41, a low refractive index layer 23X to be the second wall 23B, as illustrated in FIG. 7C.

Next, a resist film 42 is formed on the low refractive index layer 23X, as illustrated in FIG. 7D, following which the resist film 42 is patterned using a lithography technique, as illustrated in FIG. 7B. Thereafter, the resist film 42 having been patterned is used as a mask to process the low refractive index layer 23X by dry etch back, thereby forming the second wall 23B, as illustrated in FIG. 7F. Thereafter, the lens layer 24 including the plurality of on-chip lenses 24L is formed by a photolithography technique and etching. Thus, the imaging device 1 illustrated in FIG. 1 is completed.

### [Manufacturing Method 2 of Separation Wall]

It is possible to form the separation wall 23 of the present embodiment, for example, as follows.

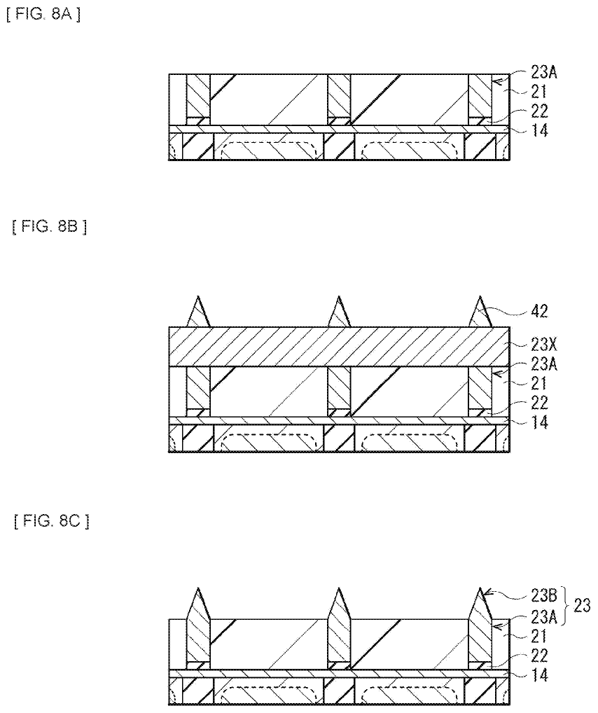

The plurality of color filters 21, the light-blocking section 22, and the first wall 23A are formed on the fixed electric charge layer 14 in a similar manner as described above, as illustrated in FIG. 8. Thereafter, the low refractive index layer 23X to be the second wall 23B is formed on the plurality of color filters 21 and the first wall 23A, as illustrated in FIG. 8B. In addition, the resist film 42 is patterned on the low refractive index layer 23X. Next, the resist film 42 is used as a mask to process the low refractive index layer 23X by dry etch back, thereby forming the second wall 23B, as illustrated in FIG. 8C. Thereafter, the lens layer 24 including the plurality of on-chip lenses 24L is formed by a photolithography technique and etching. Thus, the imaging device 1 illustrated in FIG. 1 is completed.

### [Manufacturing Method 3 of Separation Wall]

It is possible to form the separation wall 23 of the present embodiment, for example, as follows.

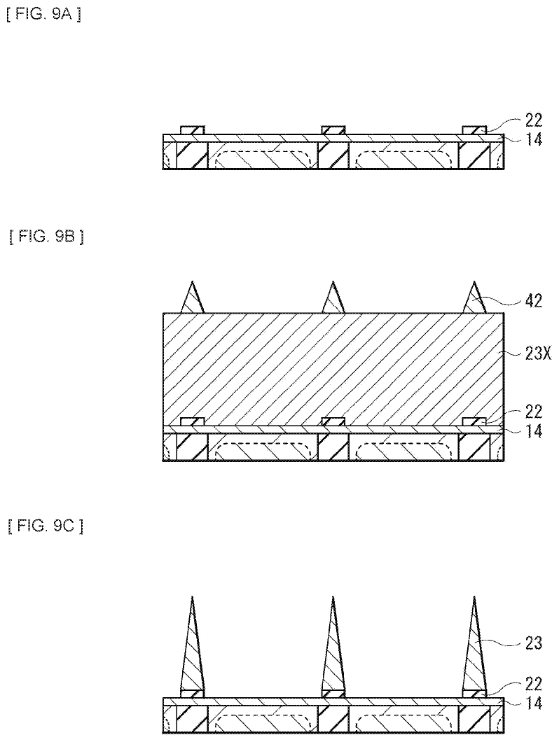

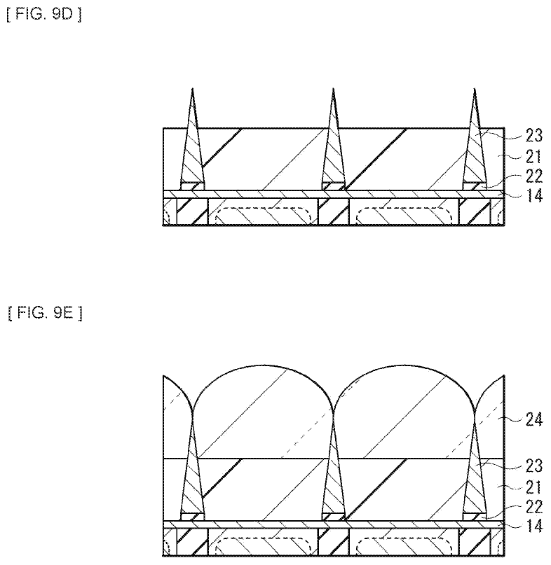

The light-blocking section 22 is formed above the element separator 13 in a similar manner as described above, as illustrated in FIG. 9A. Thereafter, for example, the low refractive index layer 23X is formed on the fixed electric charge layer 14 and the light-blocking section 22 at a predetermined thickness, following which the resist film 42 is patterned on the low refractive index layer 23X, as illustrated in FIG. 9B. Next, the separation wall 23 including the first wall 23A and the second wall 23B is collectively formed on the light-blocking section 22 using a photolithography technique, etching, and the like, as illustrated in FIG. 9C.

Thereafter, each of the color filters 21 is formed between the separation walls 23 using, for example, a photolithography technique, as illustrated in FIG. 9D. Next, the lens layer 24 including the plurality of on-chip lenses 24L is formed using a photolithography technique and etching, as illustrated in FIG. 9E. Thus, for example, the imaging device 1 illustrated in FIG. 5E is completed.

### [Manufacturing Method 4 of Separation Wall]

It is possible to form the separation wall 23 of the present embodiment, for example, as follows.

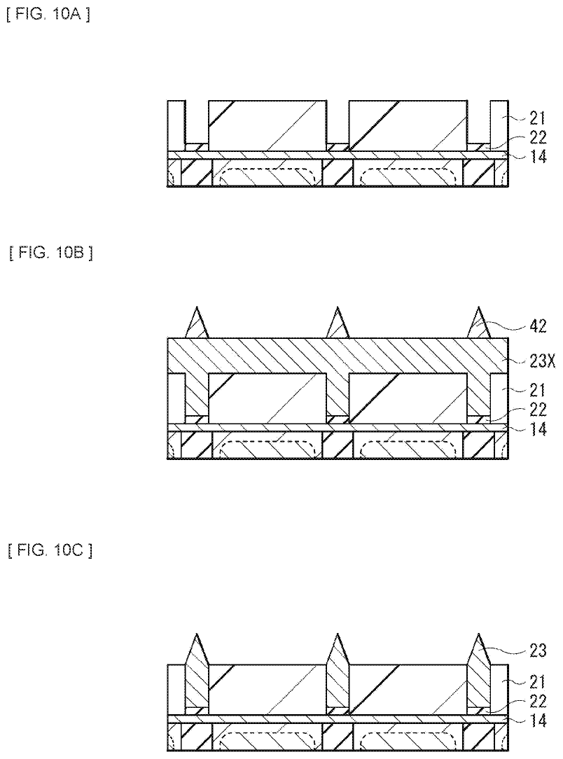

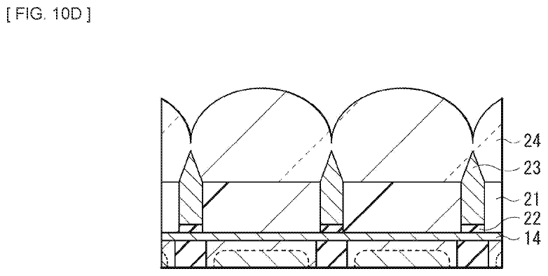

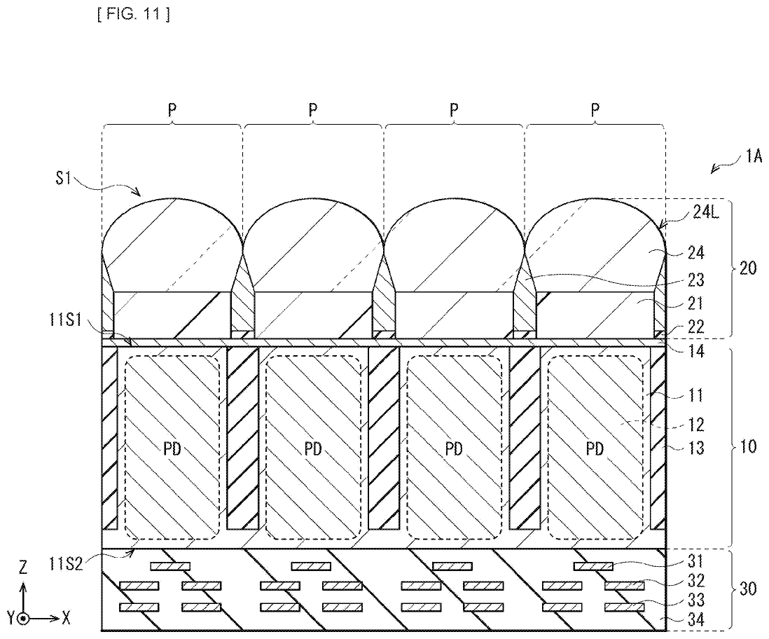

The light-blocking section 22 is formed above the element separator 13 in a similar manner as described above, following which each of the color filters 21 is formed between the light-blocking sections 22 using, for example, a photolithography technique, as illustrated in FIG. 10A. Thereafter, the low refractive index layer 23X is formed on the color filters 21 and the light-blocking section 22 at a predetermined thickness, followed by patterning the resist film 42 on the low refractive index layer 23X, as illustrated in FIG. 10B.

Next, the resist film 42 is used as a mask to process the low refractive index layer 23X having been formed on the color filters 21 using a photolithography technique, etching, and the like, as illustrated in FIG. 10C. This allows the separation wall 23 including the first wall 23A and the second wall 23B to be collectively formed. Thereafter, the lens layer 24 including the plurality of on-chip lenses 24L is formed using a photolithography technique and etching, as illustrated in FIG. 10D. Thus, for example, the imaging device 1 illustrated in FIG. 1 is completed.

### Workings and Effects

In the imaging device 1 of the present embodiment, the plurality of color filters 21 and the plurality of on-chip lenses 24L are provided at positions, on the first surface 11S1 of the semiconductor substrate 11, corresponding to respective ones of the plurality of unit pixels P disposed in a matrix, and the separation wall 23 is provided between the plurality of color filters 21 adjacent to each other. The line width of the separation wall 23 on the light incident side S1 is narrower than the line width thereof on the side of the first surface 11S1. This reduces penetration of light reflected and scattered by the separation wall 23 into the unit pixels P adjacently disposed. A description is given below of the above point.

In a typical imaging device, on-chip lenses are disposed on color filters. The on-chip lenses each condense light incident from above into a light receiver. The obliquely incident light, however, enters pixels adjacently disposed to cause occurrence of color mixing or reduction in quantum efficiency.

In contrast, in the present embodiment, the separation wall 23, whose line width on the light incident side S1 is narrower than the line width thereof on the side of the first surface 11S1, is provided between the plurality of unit pixels P adjacent to each other. This makes it possible to reduce the penetration of the light reflected or scattered by the separation wall 23 through the separation wall 23 into the unit pixels P adjacently disposed while reducing incidence of the obliquely incident light on the unit pixels P adjacently disposed.

As described above, it is possible to improve the quantum efficiency and reduce the occurrence of color mixing in the imaging device 1 of the present embodiment.

Next, a description is given of Modification Examples 1 to 8 and a second embodiment of the present disclosure. Hereinafter, components similar to those of the first embodiment described above are denoted by the same reference numerals, and a description thereof is omitted as appropriate.

### 2. MODIFICATION EXAMPLES

### 2-1. Modification Example 1

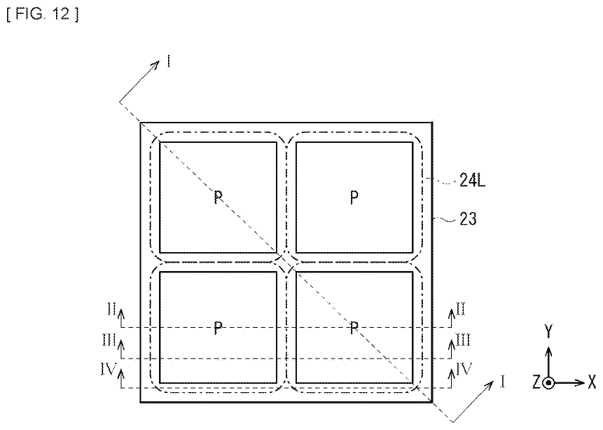

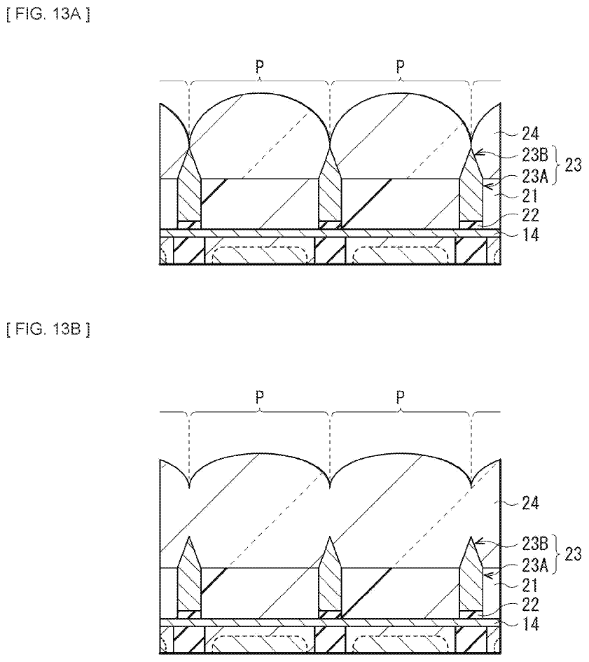

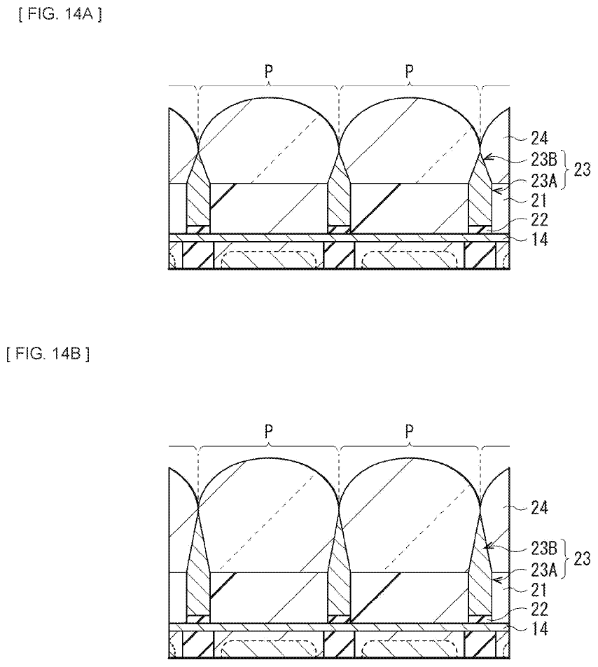

FIG. 11 schematically illustrates an example of a cross-sectional configuration of an imaging device (an imaging device 1A) according to Modification Example 1 of the present disclosure. FIG. 12 schematically illustrates an example of a planar configuration of the imaging device 1A illustrated in FIG. 11. FIG. 11 illustrates a cross-section corresponding to a line I-I illustrated in FIG. 12. The imaging device 1A is, for example, a CMOS image sensor to be used for an electronic apparatus such as a digital still camera or a video camera, and is, for example, a so-called back-illuminated imaging device in a similar manner to the first embodiment described above. The first embodiment described above indicates the example in which an upper portion of the second wall 23B is provided in the lens layer 24. However, the second wall 23B may penetrate the lens layer 24, as illustrated in FIG. 11. The imaging device 1A of the present modification example differs from the first embodiment described above in that the second wall 23B of the separation wall 23 penetrates the lens layer 24.

A height of the separation wall 23, for example, may be constant or may vary in a plane of the pixel section 100A.

FIGS. 13A and 13B schematically illustrate examples of cross-sectional configurations of the light condenser 20 corresponding to the line I-I (FIG. 13A) and a line II-II (FIG. 13B) illustrated in FIG. 12, respectively. A height of the lens layer 24 in which the plurality of on-chip lenses 24L is provided in a gapless manner differs depending on a position in each of the unit pixels P. Specifically, the height of the lens layer 24 at a boundary, corresponding to the line II-II, between the unit pixels P disposed side by side is larger than the height of the lens layer 24 at a boundary, corresponding to the line I-I, between the unit pixels P disposed on a diagonal line. Accordingly, in a case where the separation wall 23 is formed at a constant height, a gap may be formed between the upper portion of the separation wall 23 and the surface of the lens layer 24 as in the first embodiment described above, as illustrated in FIG. 13B.

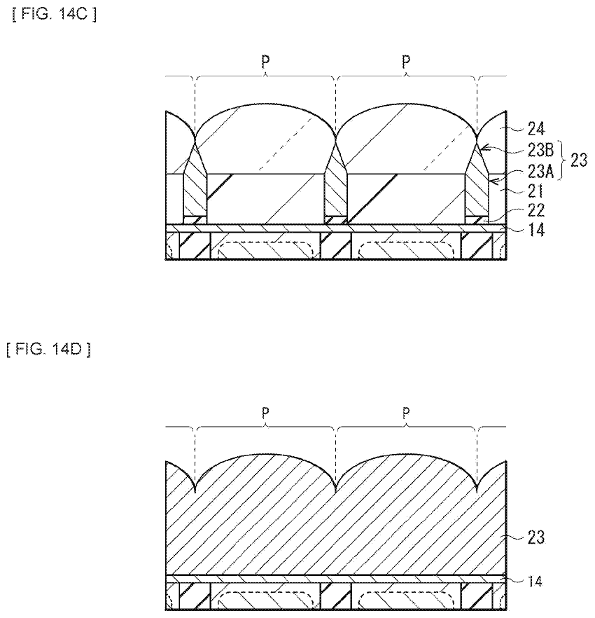

FIGS. 13A to 13D schematically illustrate examples of cross-sectional configurations of the light condenser 20 corresponding to the line I-I (FIG. 14A), the line II-II (FIG. 14B), a line III-III (FIG. 14C), and a line IV-IV (FIG. 14D) illustrated in FIG. 12, respectively. The light condenser 20 has a structure in which the separation wall 23 penetrates the lens layer 24 at any positions by, for example, causing the height of the separation wall 23 to follow a surface shape of the lens layer 24.

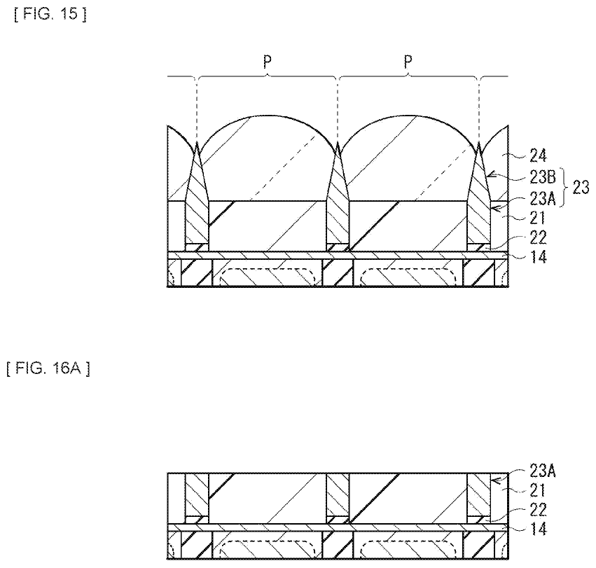

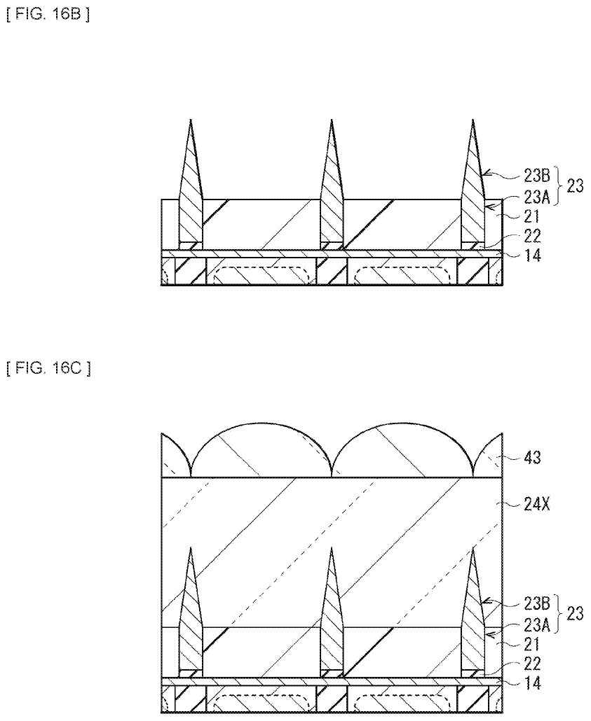

It is to be noted that FIG. 11 and the like each illustrate the example in which the upper portion of the separation wall 23 and the surface of the lens layer 24 coincide with each other; however, the present disclosure is not limited thereto. For example, the upper portion of the separation wall 23 may protrude from the surface of the lens layer 24, as illustrated in FIG. 15.

It is possible to form the separation wall 23 of the present embodiment, for example, as follows.

It is possible to form the separation wall 23 having a height that substantially coincides with the surface shape of the lens layer 24 as illustrated in FIGS. 14A to 14D, for example, as follows.

First, the plurality of color filters 21, the light-blocking section 22, and the first wall 23A are formed on the fixed electric charge layer 14 in a similar manner to the first embodiment described above, as illustrated in FIG. 16A. Thereafter, the low refractive index layer 23X to be the second wall 23B is formed on the plurality of color filters 21 and the first wall 23A, for example, to be thicker than a finished height of the on-chip lenses 24L, as illustrated in FIG. 16B. Next, a resist film is patterned on the low refractive index layer 23X and is used as a mask to process the low refractive index layer 23X by dry etch back, thereby forming the second wall 23B. Next, a lens material 24X to constitute the lens layer 24 is applied, following which a lens pattern 43 is formed on the lens material 24X, as illustrated in FIG. 16C. Thereafter, an entire surface thereof is etched back. This allows for formation of the separation wall 23 having a height that substantially coincides with the surface shape of the lens layer 24 as illustrated in FIGS. 14A to 14D.

It is to be noted that the separation wall 23 formed using the above-described method includes the second wall 23B that has, for example, a triangular cross-sectional shape as illustrated in FIG. 14B in a cross-section corresponding to the line II-II passing substantially through a middle of each of the unit pixels P, and has, for example, a trapezoidal cross-sectional shape in which the upper portion of the second wall 23B is cut, as being closer to the boundary between the adjacent unit pixels P.

As described above, the separation wall 23 penetrates the color filters 21 and the lens layer 24 in the present modification example. This makes it possible to further reduce the incidence of the obliquely incident light on the unit pixels P adjacently disposed and the penetration of the light reflected or scattered by the separation wall 23 through the separation wall 23 into the unit pixels P adjacently disposed, as compared with the first embodiment described above. Accordingly, it is possible to further improve the quantum efficiency and further reduce the occurrence of color mixing.

### 2-2. Modification Example 2

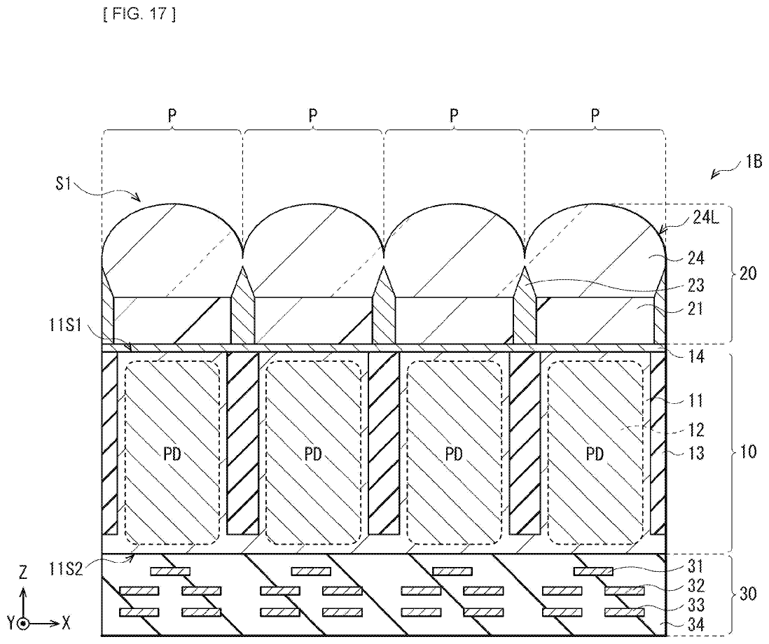

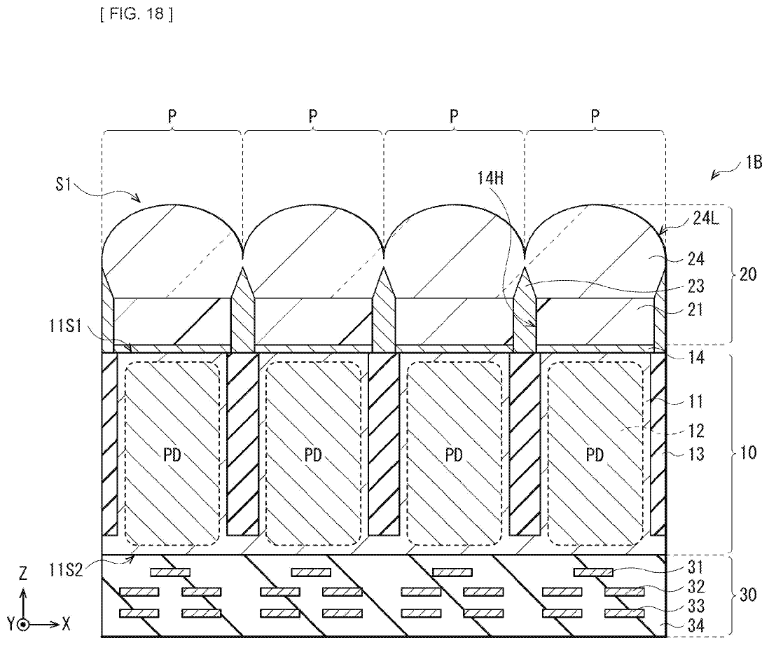

FIG. 17 schematically illustrates an example of a cross-sectional configuration of an imaging device (an imaging device 1B) according to Modification Example 2 of the present disclosure. The imaging device 1B is, for example, a CMOS image sensor to be used for an electronic apparatus such as a digital still camera or a video camera, and is, for example, a so-called back-illuminated imaging device in a similar manner to the first embodiment described above. The first embodiment described above indicates the example in which the light-blocking section 22 is provided between the fixed electric charge layer 14 and the separation wall 23. However, the light-blocking section 22 may not necessarily be provided. The imaging device 1B of the present modification example differs from the first embodiment described above in that the light-blocking section 22 is omitted.

In addition, FIG. 17 illustrates an example in which the separation wall 23 is provided on the fixed electric charge layer 14; however, the present disclosure is not limited thereto. For example, an opening 14H may be provided in the fixed electric charge layer 14, and the separation wall 23 may be directly formed on the element separator 13 provided in the semiconductor substrate 11, as illustrated in FIG. 18. This makes it possible to further reduce the penetration of the obliquely incident light through the fixed electric charge layer 14 into the unit pixels P adjacently disposed.

### 2-3. Modification Example 3

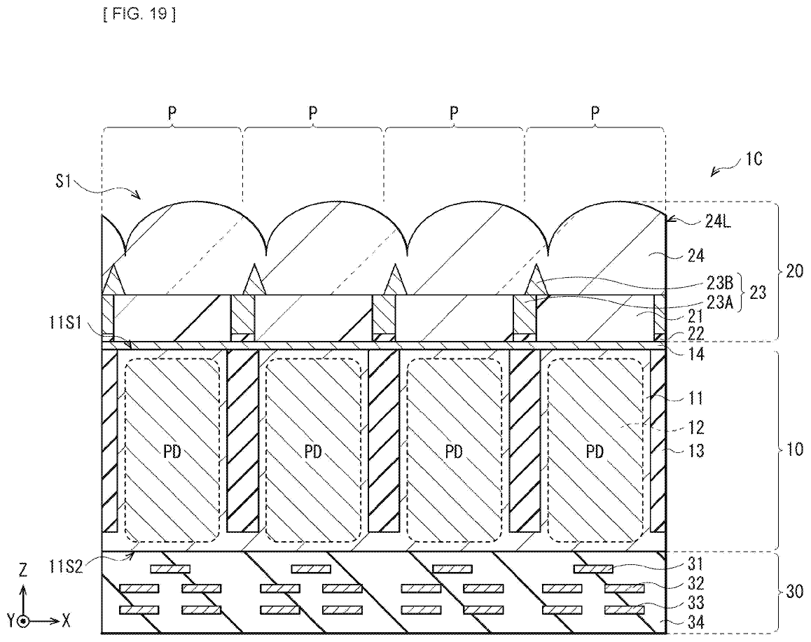

FIG. 19 schematically illustrates an example of a cross-sectional configuration of an imaging device (an imaging device 1C) according to Modification Example 3 of the present disclosure. The imaging device 1C is, for example, a CMOS image sensor to be used for an electronic apparatus such as a digital still camera or a video camera, and is, for example, a so-called back-illuminated imaging device in a similar manner to the first embodiment described above. The imaging device 1 of the first embodiment described above makes it possible to perform pupil correction by, for example, shifting the second wall 23B included in the separation wall 23 in an XY plane direction depending on a position in the plane of the pixel section 100A.

A shift direction of the second wall 23B is set to, for example, allow the second wall 23B to be shifted from a center of the pixel section 100A toward a periphery of the pixel section 100A, and from between the adjacent unit pixels P in a peripheral direction. A shift amount of the second wall 23B is larger at the periphery of the pixel section 100A than in the center of the pixel section 100A.

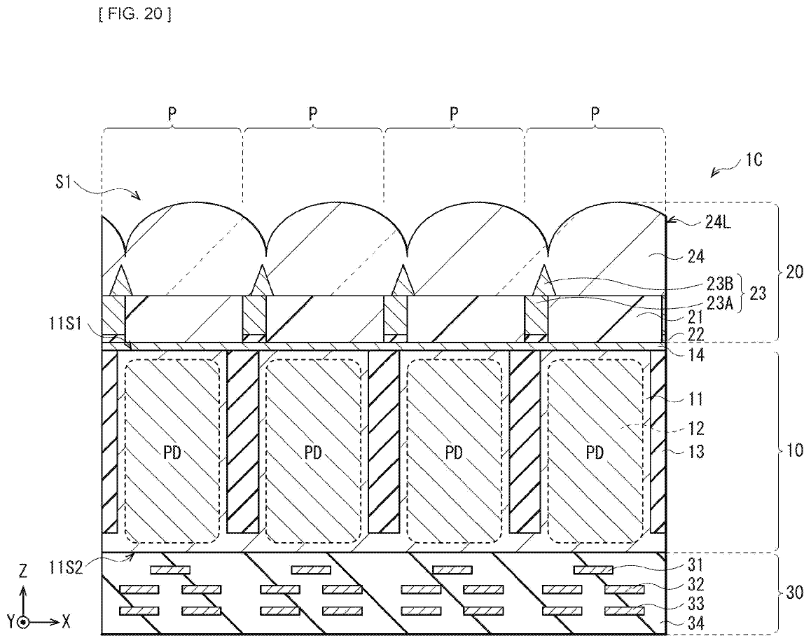

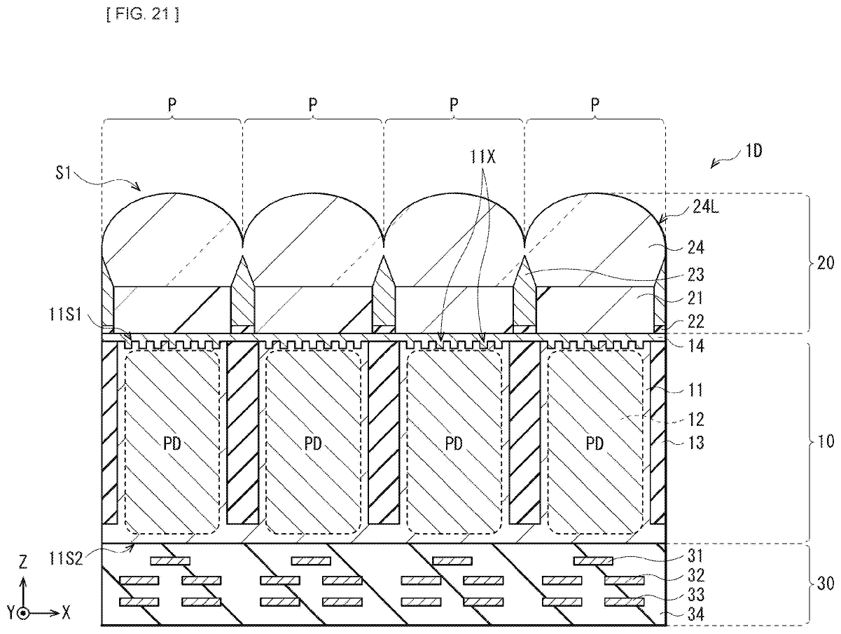

In addition, the pupil correction in the imaging device 1 may be performed by, for example, shifting the light-blocking section 22, and the first wall 23A and the second wall 23B included in the separation wall 23 in the XY plane direction depending on a position in the plane of the pixel section 100A, as illustrated in FIG. 20.

### 2-4. Modification Example 4

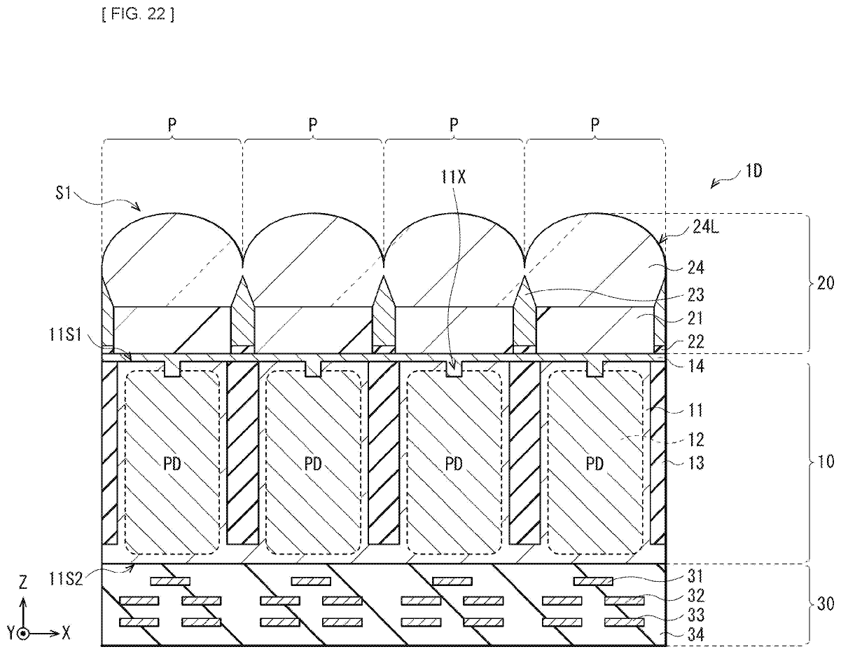

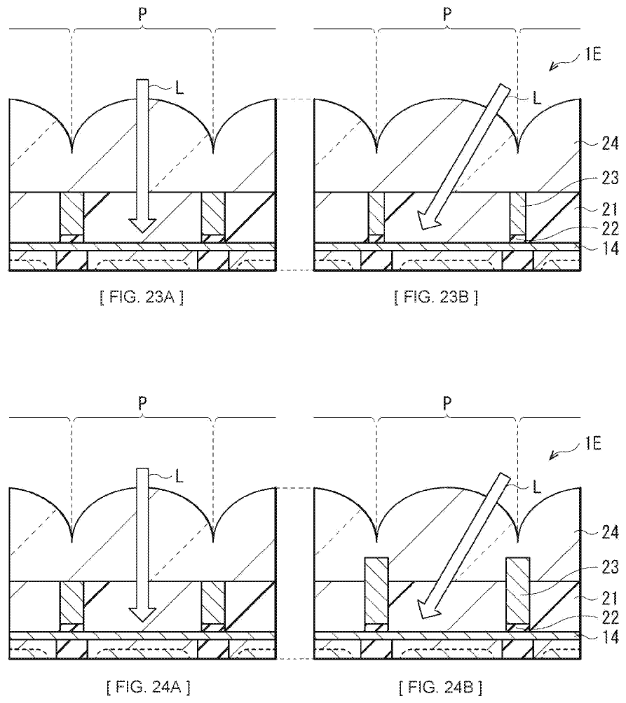

FIG. 21 schematically illustrates an example of a cross-sectional configuration of an imaging device (an imaging device 1D) according to Modification Example 4 of the present disclosure. FIG. 22 schematically illustrates another example of the cross-sectional configuration of the imaging device 1D according to Modification Example 4 of the present disclosure. The imaging device 1D is, for example, a CMOS image sensor to be used for an electronic apparatus such as a digital still camera or a video camera, and is, for example, a so-called back-illuminated imaging device in a similar manner to the first embodiment described above. The imaging device 1D of the present modification example differs from the first embodiment described above in that one or more uneven structures 11X are provided on the first surface 11S1 of the semiconductor substrate 11 for each of the unit pixels P.

The uneven structures 11X, for example, prevent reflection of incident light at the first surface 11S1 of the semiconductor substrate 11. In addition, the uneven structures 11X, for example, cause the incident light to be refracted (diffracted) by the first surface 11S1 of the semiconductor substrate 11 to secure an optical path length thereof. The uneven structures 11X may be formed, for example, in a cross shape, or may be provided, for example, in a dot shape in the plane of each of the unit pixels P. A planar shape of the dot may be any of a polygonal shape including a rectangle, or a circular shape. It is possible to form the uneven structures 11X, for example, by wet etching or dry etching.

As described above, one or more uneven structures 11X are provided on the first surface 11S1 of the semiconductor substrate 11 in the present modification example. This makes it possible to reduce the reflection of incident light at the first surface 11S1 of the semiconductor substrate 11. In addition, it is possible to secure the optical path length of the incident light incident on each of the photoelectric converters 12. Accordingly, it is possible to further improve the quantum efficiency as compared with the first embodiment described above.

### 3. SECOND EMBODIMENT

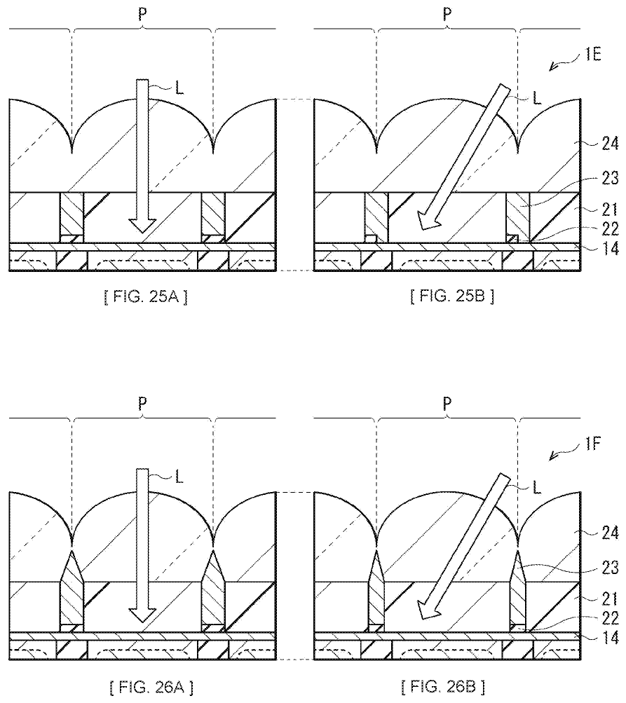

FIG. 23 schematically illustrates an example of a cross-sectional configuration of an imaging device (an imaging device 1E) according to the second embodiment of the present disclosure. FIG. 24 schematically illustrates another example of the cross-sectional configuration of the imaging device 1E according to the second embodiment of the present disclosure. FIG. 25 schematically illustrates another example of the cross-sectional configuration of the imaging device 1E according to the second embodiment of the present disclosure. The imaging device 1E is, for example, a CMOS image sensor to be used for an electronic apparatus such as a digital still camera or a video camera, and is, for example, a so-called back-illuminated imaging device in a similar manner to the first embodiment described above.

The imaging device 1E includes, for example, the plurality of color filters 21 and the plurality of on-chip lenses 24L in respective ones of the plurality of unit pixels P disposed in a matrix. The light-blocking section 22 and the separation wall 23 are provided between the plurality of color filters 21 adjacent to each other. In the imaging device 1E of the present embodiment, pupil correction is performed by changing the line width or the height of the separation wall 23, or a line width of the light-blocking section 22 depending on a position in the plane of the pixel section 100A.

In the imaging device 1D illustrated in FIG. 23, the line width of the separation wall 23 narrows from a center (A) of the pixel section 100A toward a periphery (B) of the pixel section 100A in a step-by-step manner. The line width of each of the light-blocking section 22 and the separation wall 23 is, for example, equal to or less than a line width of the element separator 13. The light-blocking section 22 may narrow, together with the separation wall 23, from the center (A) of the pixel section 100A toward the periphery (B) of the pixel section 100A in a step-by-step manner. It is to be noted that the light-blocking section 22 may be omitted.

In the imaging device 1D illustrated in FIG. 24, the height of the separation wall 23 increases from the center (A) of the pixel section 100A toward the periphery (B) of the pixel section 100A in a step-by-step manner. It is to be noted that the light-blocking section 22 may be omitted.

In the imaging device 1D illustrated in FIG. 25, the line width of the light-blocking section 22 narrows from the center (A) of the pixel section 100A toward the periphery (B) of the pixel section 100A in a step-by-step manner. In addition, the light-blocking section 22 is formed closer to a side of the center of the pixel section 100A.

As described above, pupil correction is performed by changing the line width or the height of the separation wall 23, or the line width of the light-blocking section 22 depending on a position in the plane of the pixel section 100A in the present embodiment. This makes it possible to perform the pupil correction while reducing damage to the first surface 11S1 of the semiconductor substrate 11 in a processing step, as compared with, for example, a case where the pupil correction is performed by changing a position where the light-blocking section 22 or the separation wall 23 is formed. Accordingly, it is possible to reduce dependence of light-condensing characteristics such as sensitivity on image height while preventing deterioration of element characteristics such as a dark current.

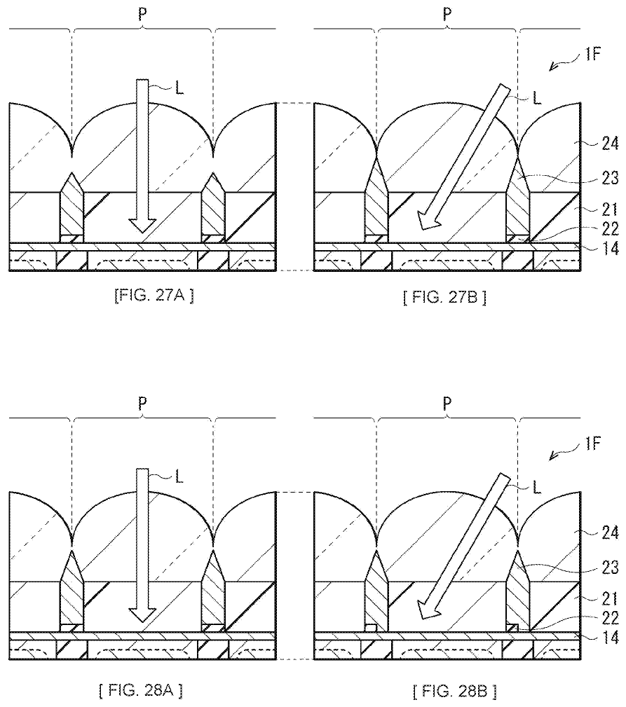

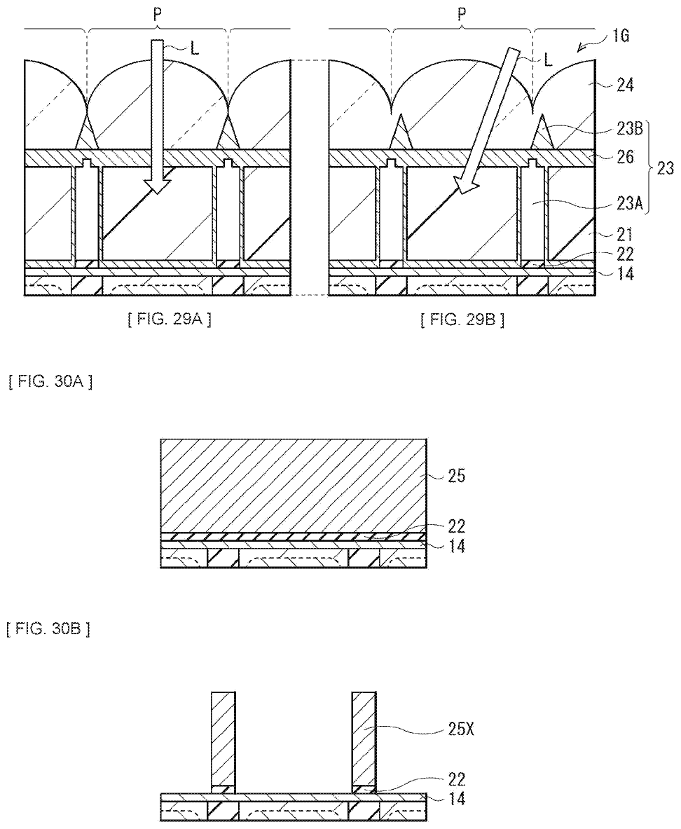

It is to be noted that FIGS. 23 to 25 each illustrate the example in which the separation wall 23 has a constant line width in the Z-axis direction; however, the present disclosure is not limited thereto. For example, the line width of the separation wall 23 in the Z-axis direction may be set to allow the line width thereof on the light incident side S1 to be narrower than the line width thereof on the side of the first surface 11S1 of the semiconductor substrate 11, in combination with the imaging device 1 of the first embodiment described above, as illustrated in FIGS. 26 to 28.

### 4. MODIFICATION EXAMPLES

### 4-1. Modification Example 5

FIG. 29 schematically illustrates an example of a cross-sectional configuration of an imaging device (an imaging device 1G) according to Modification Example 5 of the present disclosure. The imaging device 1G is, for example, a CMOS image sensor to be used for an electronic apparatus such as a digital still camera or a video camera, and is, for example, a so-called back-illuminated imaging device in a similar manner to the first embodiment described above.

The imaging device 1G includes, for example, the plurality of color filters 21 and the plurality of on-chip lenses 24L in respective ones of the plurality of unit pixels P disposed in a matrix. The light-blocking section 22 and the separation wall 23 are provided between the plurality of color filters 21 adjacent to each other. The imaging device 1G of the present modification example differs from the first embodiment described above in that the first wall 23A that penetrates the color filters 21 is formed by an air gap, and the second wall 23B that protrudes into the lens layer 24 includes a low refractive index material. In addition, the imaging device 1G of the present modification example makes it possible to perform pupil correction by shifting the position of the second wall 23B in the XY plane direction (for example, from the center (A) toward the periphery (B)) depending on a position in the plane of the pixel section 100A.

Examples of the low refractive index material of the second wall 23B include a hollow silica-containing resin material and a porous material having a refractive index of 1.1 or more and 1.45 or less. A surface of the second wall 23B may be covered with an insulating film using, for example, a low refractive index material such as silicon oxide, in a similar manner to the separation wall 23 of the first embodiment described above.

It is to be noted that the light-blocking section 22 may be omitted.

It is possible to form the separation wall 23 of the present modification example, for example, as follows.

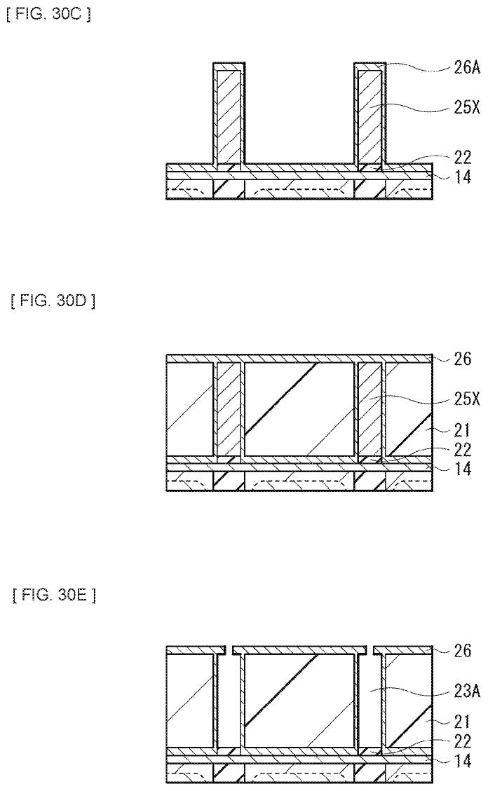

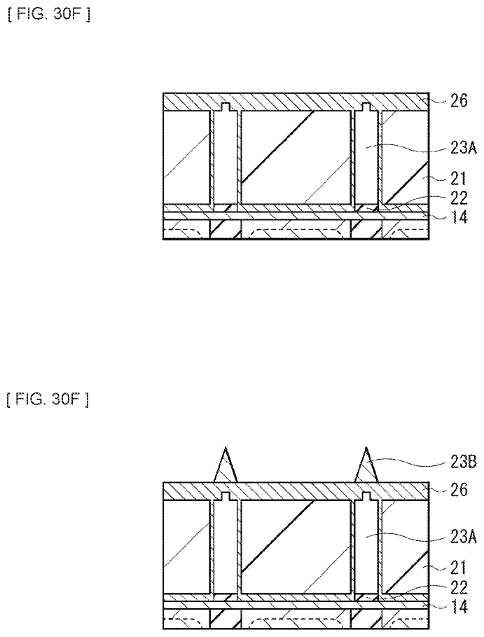

First, the fixed electric charge layer 14 is formed on the first surface 11S1 of the semiconductor substrate 11 using, for example, a chemical vapor deposition (CVD) method, sputtering, or an atomic layer deposition (ALD) method in a similar manner to the first embodiment described above. Thereafter, a metal film 22A to constitute the light-blocking section 22 and an amorphous silicon (a-Si) film 25 are formed on the fixed electric charge layer 14 using, for example, a CVD method or sputtering, as illustrated in FIG. 30A.

Next, the a-Si film 25 and a metal film 25A are processed using a photolithography technique, etching, and the like to form the light-blocking section 22 above the element separator 13, as illustrated in FIG. 30B. A structure 25X including a-Si is formed. Thereafter, an insulating film 26A on the fixed electric charge layer 14 and continuously on side surfaces and a top surface of the structure 25X is formed, as illustrated in FIG. 30C. Next, the color filters 21 are formed, following which an insulating film 26B is formed on the color filters 21 and the structure 25X, as illustrated in FIG. 30D. The insulating film 26 is configured as a cap layer 26.

Thereafter, an opening is formed in the cap layer 26 on the structure 25X using a photolithography technique, etching, and the like, following which the a-Si constituting the structure 25X is removed, as illustrated in FIG. 30E. This allows for formation of the first wall 23A including an air gap. Next, an insulating film is further formed as the cap layer 26 to block an upper portion of the air gap, as illustrated in FIG. 30F, followed by formation of the second wall 23B on the cap layer 26, as illustrated in FIG. 30G. Thereafter, the lens layer 24 including the plurality of on-chip lenses 24L is formed using a photolithography technique and etching. Thus, the imaging device 1G illustrated in FIG. 29 is completed.

As described above, in the imaging device 1G of the present modification example, the first wall 23A that penetrates the color filters 21 is formed by an air gap, and the second wall 23B that protrudes into the lens layer 24 includes a low refractive index material. This makes it possible to improve the quantum efficiency and reduce the occurrence of color mixing, in a similar manner to the first embodiment and the like described above.

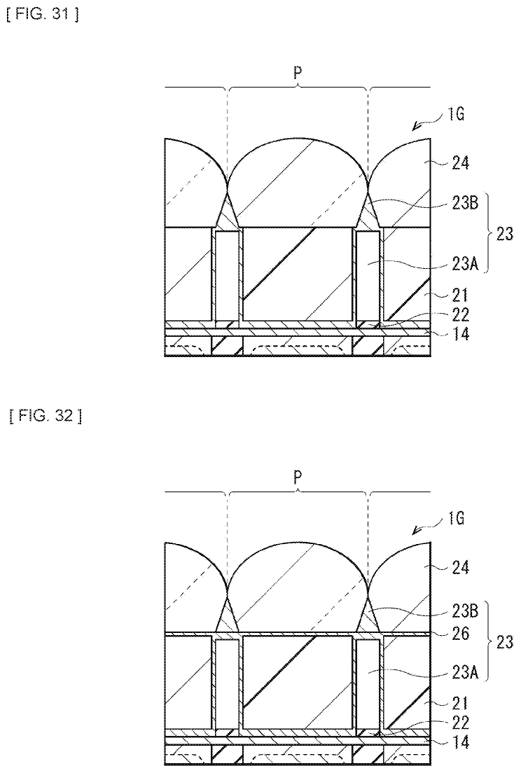

It is to be noted that FIG. 29 illustrates the example in which the second wall 23B is provided on the cap layer 26. However, the second wall 23B may be formed by processing the cap layer 26, as illustrated in FIG. 31. It is to be noted that the cap layer 26 on the color filters 21 may be completely removed as illustrated in FIG. 31, or may be partially left as illustrated in FIG. 32.

### 4-2. Modification Example 6

FIG. 33 schematically illustrates an example of a cross-sectional configuration of an imaging device (an imaging device 1H) according to Modification Example 6 of the present disclosure. The imaging device 1H is, for example, a CMOS image sensor to be used for an electronic apparatus such as a digital still camera or a video camera, and is, for example, a so-called back-illuminated imaging device in a similar manner to the first embodiment described above.

The imaging device 1H includes, for example, the plurality of color filters 21 and the plurality of on-chip lenses 24L in respective ones of the plurality of unit pixels P disposed in a matrix. The light-blocking section 22 and the separation wall 23 are provided between the plurality of color filters 21 adjacent to each other. The imaging device 1G of the present modification example differs from the first embodiment described above in that the separation wall 23 including the first wall 23A that penetrates the color filters 21 and the second wall 23B that protrudes into the lens layer 24 is formed by an air gap. In addition, in the imaging device 1G of the present modification example, it is possible to perform pupil correction by shifting the position of the second wall 23B in the XY plane direction (for example, from the center (A) toward the periphery (B)) depending on a position in the plane of the pixel section 100A.

It is possible to form the separation wall 23 of the present modification example, for example, as follows.

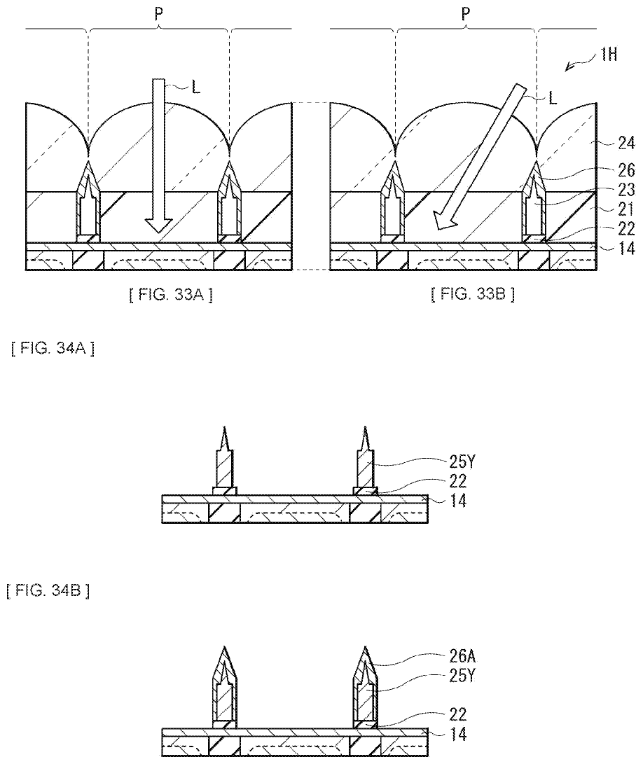

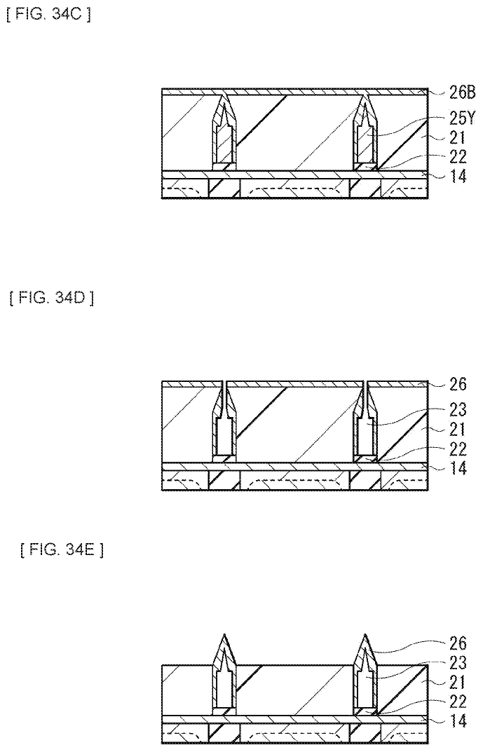

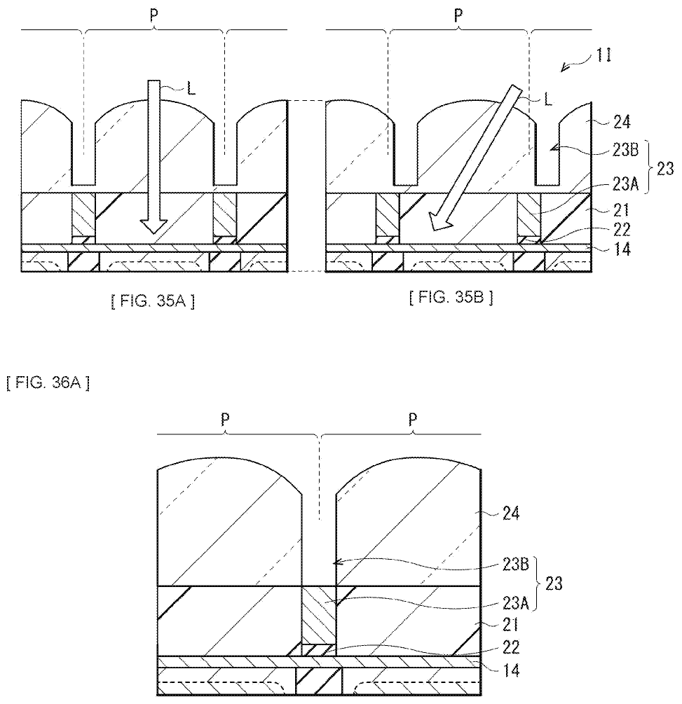

First, the fixed electric charge layer 14 is formed on the first surface 11S1 of the semiconductor substrate 11 using, for example, a chemical vapor deposition (CVD) method, sputtering, or an atomic layer deposition (ALD) method, following which the light-blocking section 22 is formed above the element separator 13 using, for example, a CVD method or sputtering, a photolithography technique, etching, and the like, in a similar manner to the first embodiment described above. Thereafter, the amorphous silicon (a-Si) film 25 is formed in a similar manner to Modification Example 5 described above, following which the a-Si film 25 is processed into an air gap shape using a photolithography technique, etching, and the like to form a structure 25Y, as illustrated in FIG. 34A.

Next, the insulating film 26A is formed continuously on side surfaces and a top surface of the structure 25Y, as illustrated in FIG. 34B. Thereafter, the color filters 21 are formed, following which the insulating film 26B is further formed, as illustrated in FIG. 34C. The insulating film 26B is configured as the cap layer 26.

Next, an opening is formed in the cap layer 26 on the structure 25Y using a photolithography technique, etching, and the like, following which the a-Si constituting the structure 25Y is removed, as illustrated in FIG. 34D. This allows for formation of the separation wall 23 including an air gap. Thereafter, an insulating film is further formed as the cap layer 26 to block an upper portion of the air gap, following which the cap layer 26 and the color filters 21 are etched back to a predetermined thickness, as illustrated in FIG. 34E. Thereafter, the lens layer 24 including the plurality of on-chip lenses 24L is formed by a photolithography technique and etching. Thus, the imaging device 1H illustrated in FIG. 33 is completed.

As described above, in the imaging device 1H of the present modification example, the first wall 23A that penetrates the color filters 21 and the second wall 23B that protrudes into the lens layer 24 are formed by an air gap. This makes it possible to improve the quantum efficiency and reduce the occurrence of color mixing, in a similar manner to the first embodiment and the like described above.

### 4-3. Modification Example 7

FIG. 35 schematically illustrates an example of a cross-sectional configuration of an imaging device (an imaging device 1I) according to Modification Example 7 of the present disclosure. The imaging device 1I is, for example, a CMOS image sensor to be used for an electronic apparatus such as a digital still camera or a video camera, and is, for example, a so-called back-illuminated imaging device in a similar manner to the first embodiment described above.

The imaging device 1I includes, for example, the plurality of color filters 21 and the plurality of on-chip lenses 24L in respective ones of the plurality of unit pixels P disposed in a matrix. The light-blocking section 22 and the separation wall 23 are provided between the plurality of color filters 21 adjacent to each other. The imaging device 1I of the present modification example differs from the first embodiment described above in that the second wall 23B formed in the lens layer 24 is formed from surfaces of the on-chip lenses 24L. In addition, in the imaging device 1I of the present modification example, it is possible to perform pupil correction by shifting the position of the second wall 23B in the XY plane direction (for example, from the center (A) toward the periphery (B)) depending on a position in the plane of the pixel section 100A.

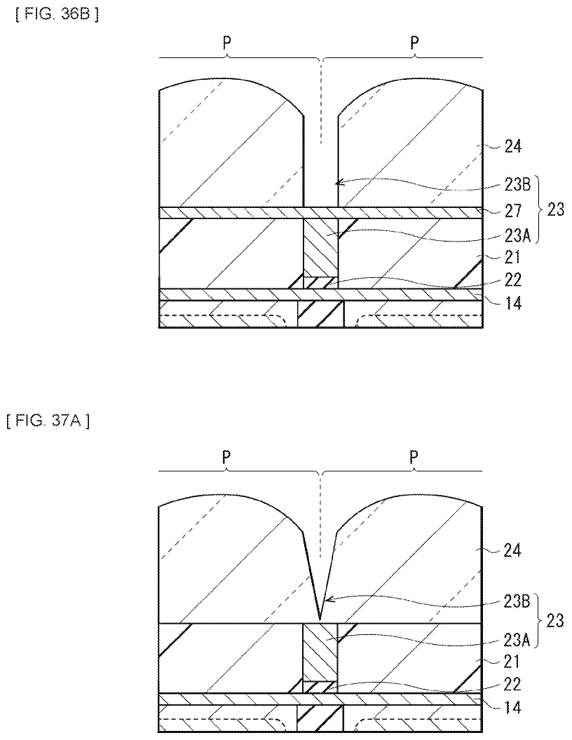

The second wall 23B is formed by, for example, an air gap. The air gap extends from the surfaces of the on-chip lenses 24L toward the first surface 11S1 of the semiconductor substrate 11. A bottom of the second wall 23B may be formed in the lens layer 24, as illustrated in FIG. 35. Alternatively, the bottom of the second wall 23B may be formed to allow the second wall 23B to penetrate the lens layer 24 to, for example, expose a surface of the first wall 23A, as illustrated in FIG. 36A, for example. In this case, an etching stopper layer 27 may be provided between the color filters 21 and the lens layer 24, as illustrated in FIG. 36B, for example. It is possible to form the etching stopper layer using, for example, an inorganic film of aluminum oxide (AlOₓ), titanium oxide (TiOₓ), silicon nitride (SiNₓ), silicon oxynitride (SiOₓN_{y}), or the like.

Further, FIG. 35 and the like each illustrate the example in which the width, i.e., the line width of the second wall 23B is the same as the line width of the first wall 23A. However, the line width of the second wall 23B may be narrower than the line width of the first wall 23A.

Furthermore, FIGS. 35, 36A, and 36B each illustrate the example in which the shape (the cross-sectional shape) of the second wall 23B is rectangular; however, the present disclosure is not limited thereto. For example, the shape (the cross-sectional shape) of the second wall 23B may be an inverted triangular shape in which the line width of the second wall 23B gradually narrows from the light incident side S1 toward the first surface 11S1 of the semiconductor substrate 11, as illustrated in FIG. 37A. Alternatively, the shape (the cross-sectional shape) of the second wall 23B may be lenticular (for example, a curved surface) at the bottom, as illustrated in FIG. 37B.

It is to be noted that the second wall 23B may include, for example, the low refractive index material or the light-absorbing material described above, in addition to an air gap. Similarly, the first wall 23A may be formed by an air gap in a similar manner to Modification Example 5 described above.

In addition, it is also possible to perform pupil correction by, in addition to shifting the position of the second wall 23B in the XY plane direction, narrowing the line width of the second wall 23B from the center (A) toward the periphery (B) in a step-by-step manner or increasing a depth of the second wall 23B from the center (A) toward the periphery (B) in a step-by-step manner.

It is possible to form the separation wall 23 of the present modification example, for example, as follows.

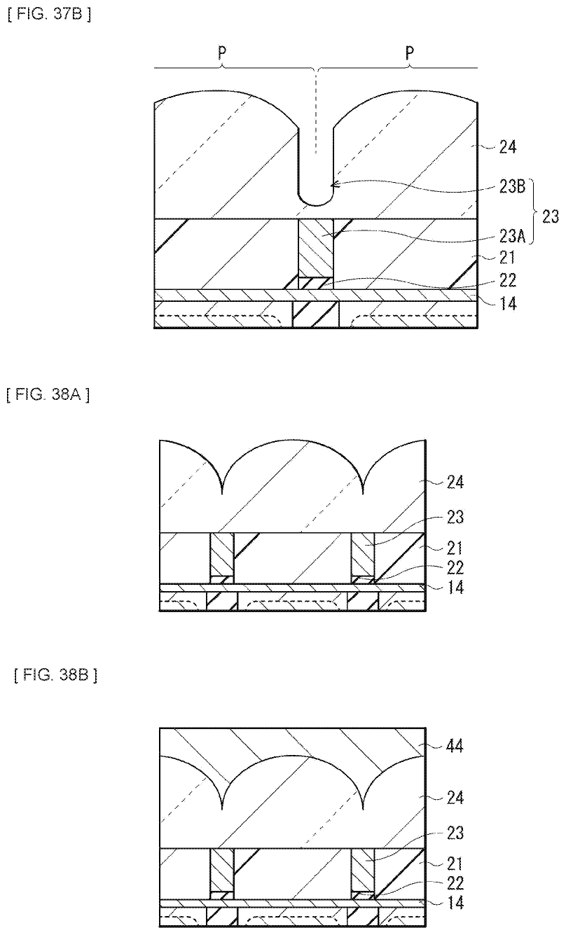

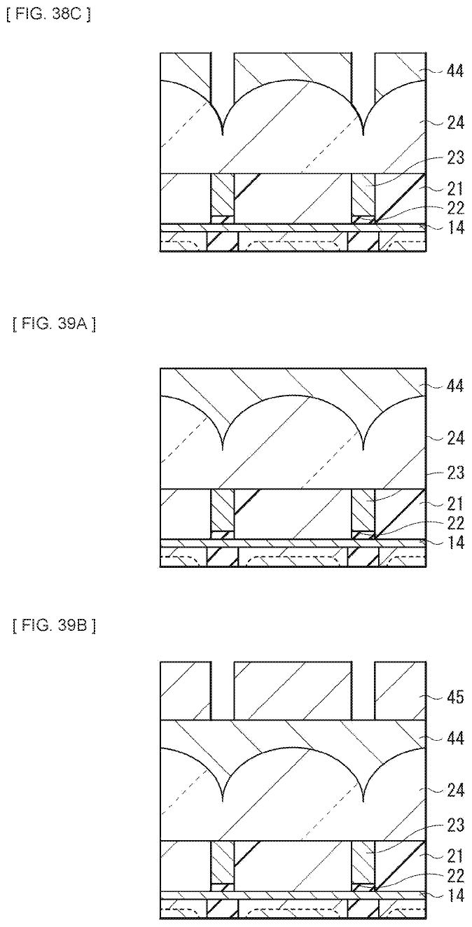

First, each of the color filters 21 is formed between the first walls 23A using a photolithography technique, following which the lens layer 24 including the plurality of on-chip lenses 24L is formed using a photolithography technique and etching, in a similar manner to the first embodiment described above, as illustrated in FIG. 38A. Next, a resist film 44 is formed on the lens layer 24 to planarize a surface thereof, as illustrated in FIG. 38B. Thereafter, the resist film 44 is patterned by a photolithography technique, followed by etching the lens layer 24 by dry etching, for example, to form the second wall 23B, as illustrated in FIG. 38C. Thus, the imaging device 1I illustrated in FIG. 35 is completed.

In addition thereto, it is possible to form the separation wall 23 of the present modification example, for example, as follows.

First, the resist film 44 is formed on the lens layer 24 to planarize the surface thereof in a similar manner as described above, as illustrated in FIG. 39A. Next, a resist film 45 including a material different from that of the resist film 44 is patterned on the resist film 44, as illustrated in FIG. 39B. Thereafter, the lens layer 24 is etched together with the resist film 44 by dry etching, for example, to form the second wall 23B. Thus, the imaging device 1I illustrated in FIG. 35 is completed.

It is to be noted that in a case where the line width of the second wall 23B narrows from the center (A) toward the periphery (B) in a step-by-step manner as described above, it is possible to achieve the shape in which the line width of the second wall 23B narrows from the center (A) toward the periphery (B) in a step-by-step manner by changing a pattern of the resist film 44 for each image height.

As described above, in the imaging device 1I of the present modification example, the second wall 23B is formed by, for example, an air gap extending from the surfaces of the on-chip lenses 24L toward the first surface 11S1 of the semiconductor substrate 11. This makes it possible to achieve effects described below in addition to the effects of the first embodiment described above. For example, it is possible to achieve high waveguiding effects as compared with a case where the second wall 23B includes a low refractive index material. In addition, it is possible to simplify a manufacturing process as compared with Modification Example 5 and Modification Example 6 described above. Further, forming the first wall 23A and the second wall 23B separately enables respective shapes and materials thereof to be adjusted. Furthermore, pupil correction is not to be performed regarding a positional relationship between the element separator 13 and the first wall 23A, thus making it possible to reduce processing damage to the pixel section 100A. Accordingly, it is possible to reduce the dependence of the light-condensing characteristics such as sensitivity on image height.

### 4-4. Modification Example 8

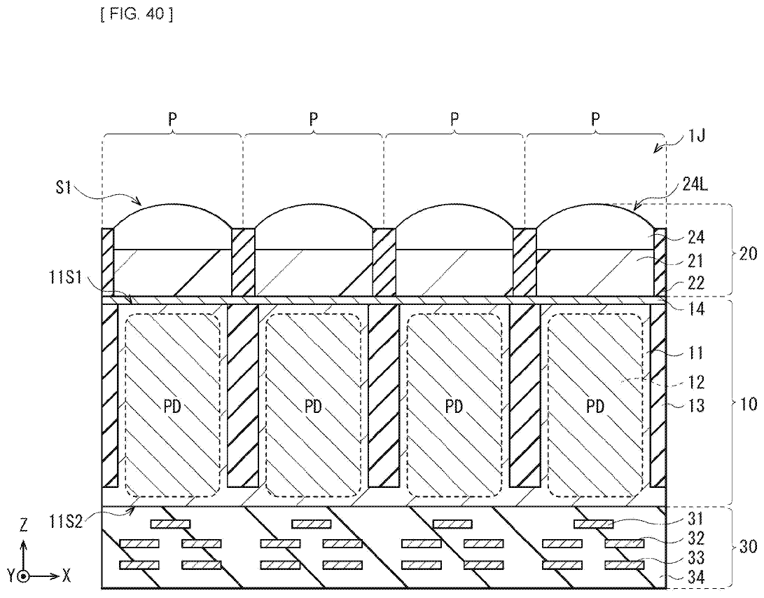

FIG. 40 schematically illustrates an example of a cross-sectional configuration of an imaging device (an imaging device 1J) according to Modification Example 8 of the present disclosure. The imaging device 1J is, for example, a CMOS image sensor to be used for an electronic apparatus such as a digital still camera or a video camera, and is, for example, a so-called back-illuminated imaging device in a similar manner to the first embodiment described above.

The imaging device 1J includes, for example, the plurality of color filters 21 and the plurality of on-chip lenses 24L in respective ones of the plurality of unit pixels P disposed in a matrix. The light-blocking section 22 and the separation wall 23 are provided between the plurality of color filters 21 adjacent to each other. The imaging device 1J of the present modification example differs from the first embodiment described above in that the light-blocking section 22 is a specific example of a “separation wall” of the present disclosure and is selectively provided between the color filters 21 of different colors, and a portion of the light-blocking section 22 protrudes into the lens layer 24.

The light-blocking section 22 includes, for example, an electrically conductive material having a light-blocking property. Specific examples thereof include tungsten (W), silver (Ag), copper (Cu), titanium (Ti), aluminum (Al), and alloys thereof. In addition thereto, it is possible for the light-blocking section 22 to include, for example, a black paint such as carbon black.

It is possible for the lens layer 24 to include, for example, a resin material, such as Styrene Thermosetting Resin (STSR), having a refractive index of 1.4 or more and 1.6 or less, or a high refractive index material, such as silicon nitride (SiNₓ), having a refractive index of 1.9 or more.

As described above, in the imaging device 1J of the present modification example, the light-blocking section 22 is selectively provided between the color filters 21 of different colors, and the portion of the light-blocking section 22 protrudes into the lens layer 24, thereby providing the separation wall that prevents the light obliquely incident from the light incident side S1 from leaking into the adjacent unit pixels P. Accordingly, in addition to the effects of the first embodiment described above, it is possible to reduce leakage of the obliquely incident light into the adjacent unit pixels P. The leakage is, for example, due to the light being reflected by the first surface 11S1 of the semiconductor substrate 11 or the like and further being reflected again by a surface opposed to the first surface 11S1 of the lens layer 24. Therefore, it is possible to suppress occurrence of a flare.

### 5. APPLICATION EXAMPLES

### Application Example 1

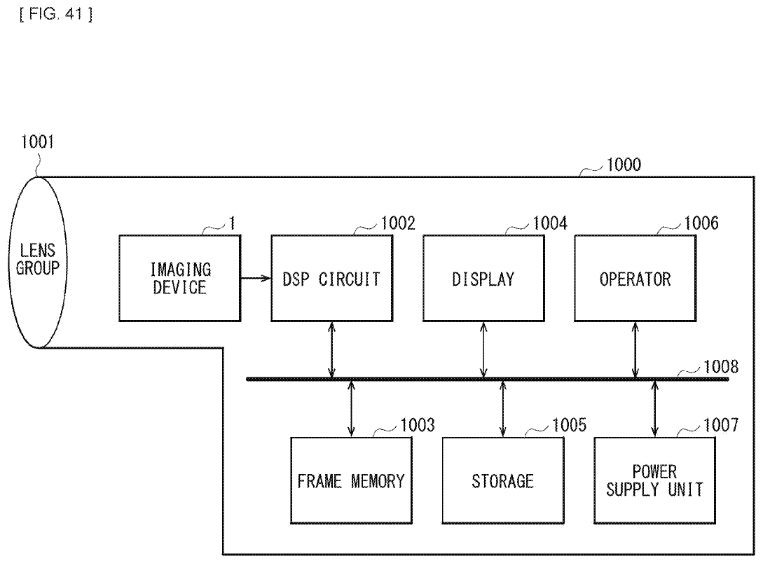

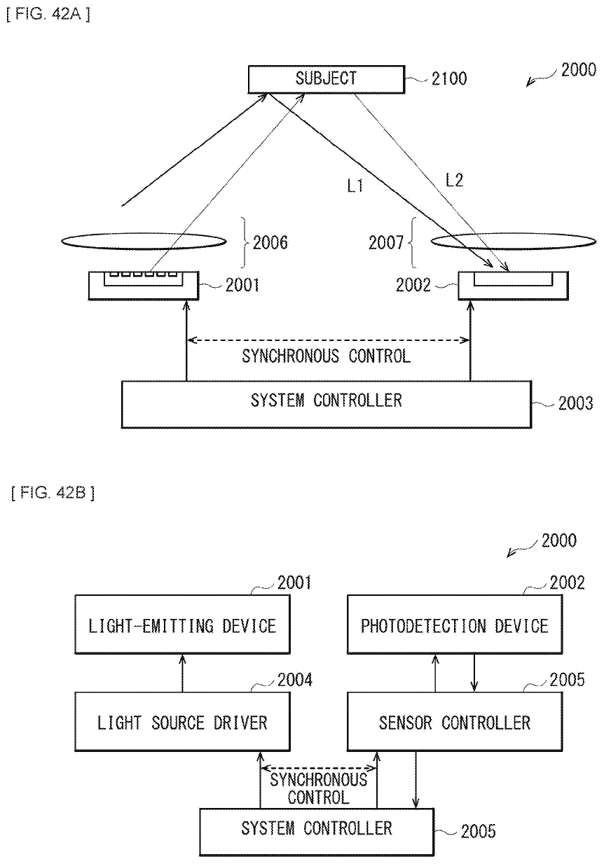

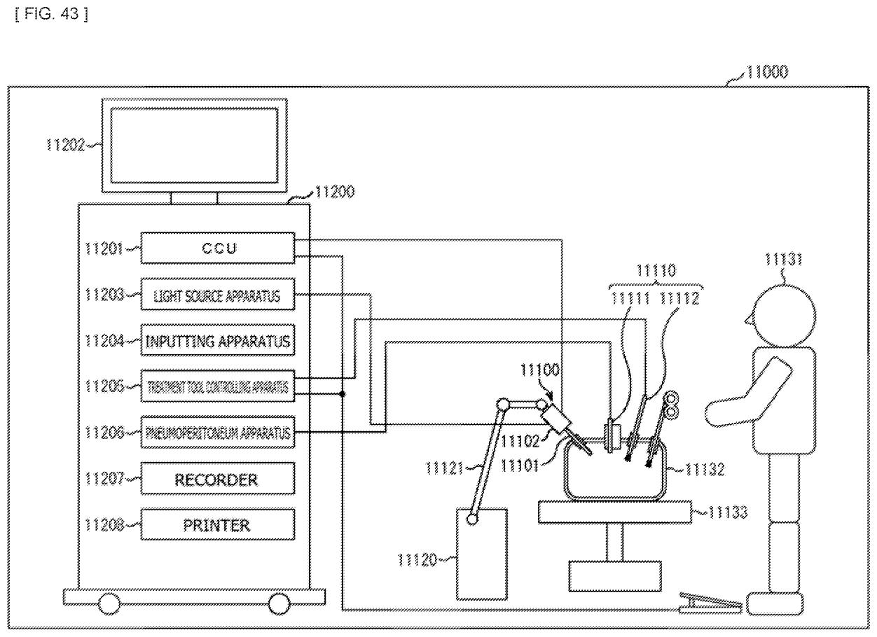

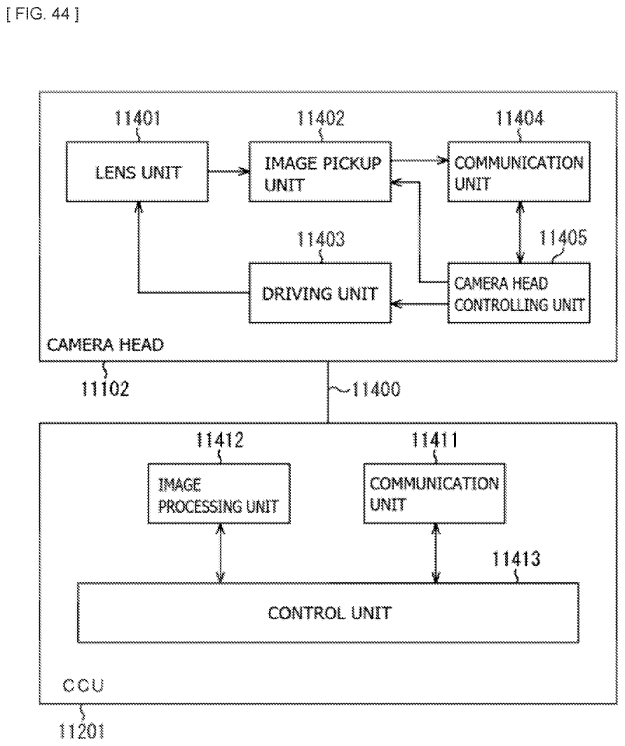

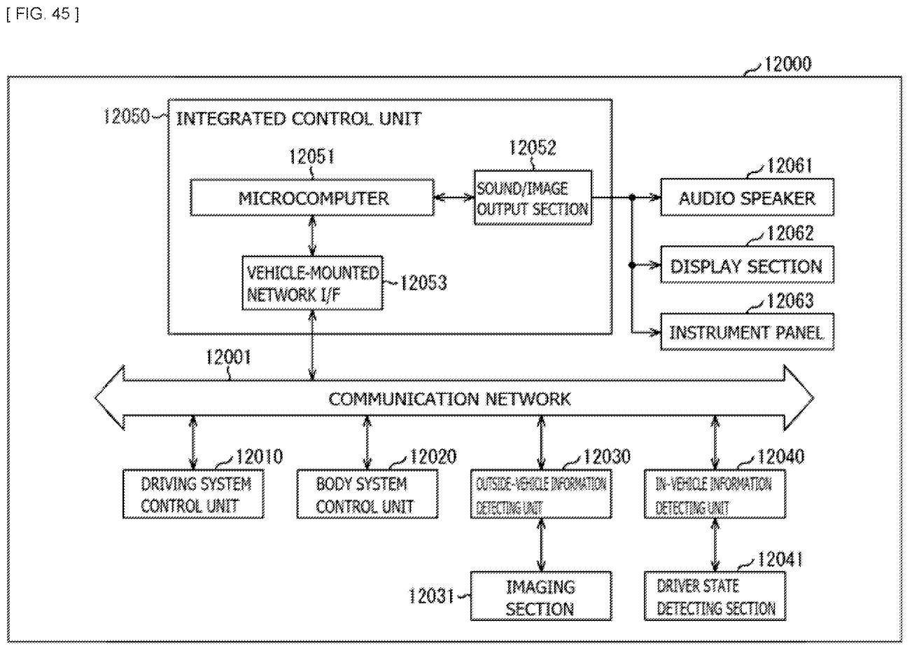

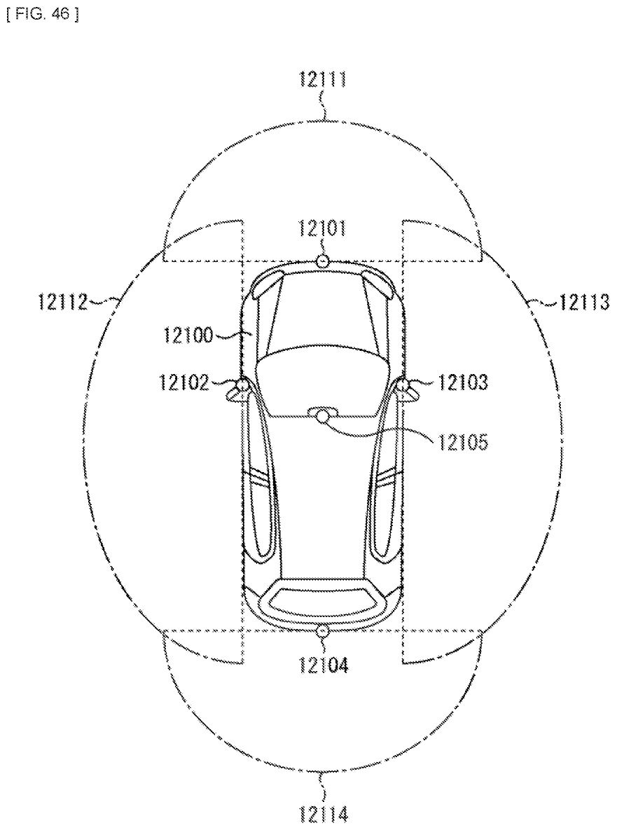

The imaging device 1 and the like described above are applicable to various kinds of electronic apparatuses having imaging functions. Examples of the electronic apparatuses include camera systems such as digital still cameras or video cameras and mobile phones having the imaging functions. FIG. 41 illustrates a schematic configuration of an electronic apparatus 1000.

The electronic apparatus 1000 includes, for example, the lens group 1001, the imaging device 1, a DSP (Digital Signal Processor) circuit 1002, a frame memory 1003, a display 1004, a recorder 1005, an operator 1006, and a power supply unit 1007, which are coupled to each other through a bus line 1008.

The lens group 1001 takes in incident light (image light) from a subject to form an image on an imaging plane of the imaging device 1. The imaging device 1 converts a light amount of the incident light, the image of which is formed on the imaging plane by the lens group 1001, into an electric signal on a pixel-by-pixel basis, and supplies the electric signal as a pixel signal to the DSP circuit 1002.

The DSP circuit 1002 is a signal processing circuit that processes a signal supplied from the imaging device 1. The DSP circuit 1002 outputs image data obtained by processing the signal from the imaging device 1. The frame memory 1003 temporarily holds the image data processed by the DSP circuit 1002 on a frame-by-frame basis.

The display 1004 includes, for example, a panel-type display device such as a liquid crystal panel or an organic EL (Electro Luminescence) panel, and records image data of a moving image or a still image captured by the imaging device 1, on a recording medium such as a semiconductor memory or a hard disk.

The operator 1006 outputs, in accordance with an operation by a user, an operation signal concerning various functions of the electronic apparatus 1000. The power supply unit 1007 supplies the DSP circuit 1002, the frame memory 1003, the display 1004, the recorder 1005, and the operator 1006 with various types of power as power for operating these supply targets as appropriate.

### Application Example 2

FIG. 42A schematically illustrates an example of an overall configuration of a photodetection system 2000 including the imaging device 1. FIG. 42B illustrates an example of a circuit configuration of the photodetection system 2000. The photodetection system 2000 includes a light-emitting device 2001 as a light source unit that emits infrared light L2, and a photodetection device 2002 as alight receiver including a photoelectric conversion element. The imaging device 1 described above is usable as the photodetection device 2002. The photodetection system 2000 may further include a system controller 2003, a light source driver 2004, a sensor controller 2005, a light source-side optical system 2006, and a camera-side optical system 2007.

The photodetector 2002 is configured to detect light L1 and the light L2. The light L1 is ambient light from the outside reflected by a subject (a measurement object) 2100 (FIG. 42A). The light L2 is light emitted from the light-emitting device 2001 and then reflected by the subject 2100. The light L1 is, for example, visible light, and the light L2 is, for example, infrared light. The light L1 is detectable by a photoelectric converter in the photodetection device 2002, and the light L2 is detectable by a photoelectric conversion region in the photodetection device 2002. It is possible to obtain image information on the subject 2100 from the light L1 and obtain information on a distance between the subject 2100 and the photodetection system 2000 from the light L2. It is possible to mount the photodetection system 2000 on, for example, an electronic apparatus such as a smartphone or a mobile body such as a car. It is possible to configure the light-emitting device 2001 with, for example, a semiconductor laser, a surface-emitting semiconductor laser, or a vertical cavity surface emitting laser (VCSEL). As a method of detecting the light L2 emitted from the light-emitting device 2001 by the photodetection device 2002, for example, it is possible to adopt an iTOF method; however, the method is not limited thereto. In the iTOF method, the photoelectric converter is configured to measure a distance to the subject 2100 by time of flight (Time-of-Flight; TOF), for example. As the method of detecting the light L2 emitted from the light-emitting device 2001 by the photodetection device 2002, it is also possible to adopt, for example, a structured light method or a stereovision method. For example, in the structured light method, light having a predetermined pattern is projected on the subject 2100, and distortion of the pattern is analyzed, thereby making it possible to measure the distance between the photodetection system 2000 and the subject 2100. In addition, in the stereovision method, for example, two or more cameras are used to acquire two or more images of the subject 2100 viewed from two or more different viewpoints, thereby making it possible to measure the distance between the photodetection system 2000 and the subject. It is to be noted that it is possible to synchronously control the light-emitting device 2001 and the photodetection device 2002 by the system controller 2003.

### 6. PRACTICAL APPLICATION EXAMPLES

### (Example of Practical Application to Endoscopic Surgery System)

The technology according to the present disclosure (the present technology) is applicable to various products. For example, the technology according to the present disclosure may be applied to an endoscopic surgery system.

FIG. 43 is a view depicting an example of a schematic configuration of an endoscopic surgery system to which the technology according to an embodiment of the present disclosure (present technology) can be applied.

In FIG. 43, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photoelectrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 44 is a block diagram depicting an example of a functional configuration of the camera head 11102 and the CCU 11201 depicted in FIG. 43.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure may be applied has been described above. The technology according to the present disclosure may be applied to the image pickup unit 11402 among the configurations described above. Applying the technology according to the present disclosure to the image pickup unit 11402 improves detection accuracy.

It is to be noted that the endoscopic surgery system has been described here as an example; however, the technology according to the present disclosure may be additionally applied to, for example, a microscopic surgery system.

### (Example of Practical Application to Mobile Body)

The technology according to the present disclosure is applicable to various products. For example, the technology according to the present disclosure may be achieved as an apparatus to be mounted on a mobile body of any kind such as an automobile, an electric vehicle, a hybrid electric vehicle, a motorcycle, a bicycle, a personal mobility, an airplane, a drone, a vessel, a robot, a construction machine, and an agricultural machine (tractor).

FIG. 45 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 45, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 45, an audio speaker 12061, a display section 12062, and an instrument panel 12063 are illustrated as the output device. The display section 12062 may, for example, include at least one of an on-board display and a head-up display.

FIG. 46 is a diagram depicting an example of the installation position of the imaging section 12031.

In FIG. 46, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 46 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the mobile body control system to which the technology according to the present disclosure may be applied has been described above. The technology according to the present disclosure may be applied to the imaging section 12031 among the configurations described above. Specifically, the imaging device (for example, the imaging device 1) according to any of the first and second embodiments described above and Modification Examples 1 to 8 thereof is applicable to the imaging section 12031. Applying the technology according to the present disclosure to the imaging section 12031 makes it possible to obtain a high-definition captured image with less noise. This makes it possible to perform highly accurate control using the captured image in the mobile body control system.

Although the present disclosure has been described above with reference to the first and second embodiments, Modification Examples 1 to 8, the application examples, and the practical application examples, the present technology is not limited to the embodiments and the like described above, and may be modified in a variety of ways. For example, Modification Examples 1 to 8 described above have been described as modification examples of the first embodiment described above; however, it is possible to combine configurations of the respective modification examples and the second embodiment as appropriate.

It is to be noted that the effects described herein are merely exemplary and are not limited to the description thereof, and other effects may be provided.

It is to be noted that the present disclosure may also have the following configurations. According to the present technology of the following configurations, a plurality of color filters and a plurality of condensing lenses are stacked in this order on a side of a first surface of a semiconductor substrate in respective ones of a plurality of pixels, the semiconductor substrate having the first surface and a second surface opposed to each other. In addition, a separation wall whose line width on a light incident side is narrower than a line width thereof on the side of the first surface is provided between the plurality of pixels adjacent to each other. This makes it possible to reduce penetration of light reflected and scattered by the separation wall into the adjacent pixels. Accordingly, it is possible to improve the quantum efficiency and reduce the occurrence of color mixing.

(1)

An imaging device including:
a semiconductor substrate having a first surface and a second surface opposed to each other, the semiconductor substrate including a plurality of pixels disposed in a matrix, and a plurality of photoelectric converters that each generates, through photoelectric conversion, electric charge corresponding to an amount of received light for each of the pixels;
a plurality of color filters provided on a side of the first surface in respective ones of the plurality of pixels;
a plurality of condensing lenses provided on a light incident side of the plurality of color filters in the respective ones of the plurality of pixels; and
a separation wall provided between the plurality of color filters adjacent to each other on the side of the first surface, the separation wall having a line width on the light incident side narrower than the line width of the separation wall on the side of the first surface.
   (2)

The imaging device according to (1), in which the separation wall includes a first wall that penetrates the plurality of color filters, and a second wall that protrudes into the condensing lenses.

(3)

The imaging device according to (2), in which at least a line width of the second wall of the separation wall narrows toward the light incident side.

(4)

The imaging device according to any one of (1) to (3), in which the line width of the separation wall continuously varies from the side of the first surface toward the light incident side.

(5)

The imaging device according to any one of (1) to (4), in which the line width of the separation wall varies stepwise from the side of the first surface toward the light incident side.

(6)

The imaging device according to any one of (2) to (5), in which the second wall penetrates the plurality of condensing lenses.

(7)

The imaging device according to any one of (1) to (6), in which a height of the separation wall substantially coincides with a surface shape of the plurality of condensing lenses in a plane of a pixel section, the pixel section including the plurality of pixels disposed in a matrix.

(8)

The imaging device according to any one of (1) to (7), in which a height of the separation wall differs depending on a position in a plane of a pixel section, the pixel section including the plurality of pixels disposed in a matrix.

(9)

The imaging device according to (8), in which the height of the separation wall increases from a center of the pixel section toward a periphery of the pixel section.

(10)

The imaging device according to any one of (1) to (9), in which the line width of the separation wall differs depending on a position in a plane of a pixel section, the pixel section including the plurality of pixels disposed in a matrix.

(11)

The imaging device according to (10), in which the line width of the separation wall narrows from a center of the pixel section toward a periphery of the pixel section.

(12)

The imaging device according to any one of (1) to (11), in which a position where the separation wall is formed differs depending on a position in a plane of a pixel section, the pixel section including the plurality of pixels disposed in a matrix.

(13)

The imaging device according to (12), in which
the separation wall includes a first wall that penetrates the plurality of color filters and a second wall that protrudes into the condensing lenses, and
the second wall is formed at a position shifted from a center of the pixel section toward a periphery of the pixel section, and from between the plurality of pixels adjacent to each other in a direction of the periphery.
   (14)

The imaging device according to (12) or (13), in which an entirety of the separation wall is formed at a position shifted from a center of the pixel section toward a periphery of the pixel section, and from between the plurality of pixels adjacent to each other in a direction of the periphery.

(15)

The imaging device according to any one of (1) to (14), in which the separation wall includes a material having a refractive index lower than the plurality of condensing lenses, or a metal material that absorbs incident light.

(16)

The imaging device according to any one of (1) to (15), in which
the plurality of color filters includes a resin material, and
the plurality of condensing lenses includes one of a resin material having a refractive index of 1.5 or more and 2.0 or less, silicon nitride, silicon oxynitride, silicon oxide, or amorphous silicon.
   (17)

The imaging device according to any one of (1) to (16), further including a light-blocking section provided between the first surface and the separation wall.

(18)

The imaging device according to (17), in which the light-blocking section is provided in a lattice pattern in a plane of a pixel section, the pixel section including the plurality of pixels disposed in a matrix, and a line width of the light-blocking section differs depending on a position in the plane of the pixel section.

(19)

The imaging device according to (18), in which the line width of the light-blocking section narrows from a center of the pixel section toward a periphery of the pixel section.

(20)

The imaging device according to (19), in which the light-blocking section is formed at a position shifted from between the plurality of pixels adjacent to each other toward the center of the pixel section as being closer to the periphery of the pixel section.

(21)

The imaging device according to any one of (1) to (20), in which the plurality of condensing lenses is disposed in a gapless manner.

(22)

The imaging device according to any one of (1) to (21), further including an element separator provided between the plurality of pixels adjacent to each other, the element separator extending from the first surface toward the second surface of the semiconductor substrate.

(23)

The imaging device according to (22), in which
the element separator is provided in a lattice pattern in a plane of a pixel section, the pixel section including the plurality of pixels disposed in a matrix, and
the separation wall is formed above the element separator.
   (24)

The imaging device according to (23), in which the line width of the separation wall is equal to or less than a line width of the element separator.

(25)

The imaging device according to any one of (1) to (24), in which the semiconductor substrate includes an uneven structure on the first surface in each of the plurality of pixels.

(26)

The imaging device according to any one of (2) to (25), in which
the first wall is formed by an air gap, and
the second wall includes a low refractive index material having a refractive index of 1.1 or more and 1.45 or less.
   (27)

The imaging device according to any one of (2) to (25), in which the first wall and the second wall are formed by an air gap.

(28)

The imaging device according to any one of (2) to (27), in which the second wall extends from light incident surfaces of the condensing lenses toward the first surface of the semiconductor substrate.

(29)

The imaging device according to any one of (1) to (28), further including a light-blocking section provided between the first surface and the separation wall, in which the light-blocking section also serves as the separation wall.

(30)

The imaging device according to (29), in which the light-blocking section includes tungsten, aluminum, or carbon black.

(31)

An imaging device including:
a semiconductor substrate having a first surface and a second surface opposed to each other, the semiconductor substrate including a plurality of pixels disposed in a matrix, and a plurality of photoelectric converters that each generates, through photoelectric conversion, electric charge corresponding to an amount of received light for each of the pixels;
a plurality of color filters provided on a side of the first surface in respective ones of the plurality of pixels;
a plurality of condensing lenses provided on a light incident side of the plurality of color filters in the respective ones of the plurality of pixels; and
a separation wall provided between the plurality of color filters adjacent to each other on the side of the first surface, the separation wall penetrating through the plurality of color filters, the separation wall having a height, a line width, or both that differ depending on a position in a plane of a pixel section, the pixel section including the plurality of pixels disposed in a matrix.
   (32)

The imaging device according to (31), further including a light-blocking section provided between the first surface and the separation wall, in which
the light-blocking section has a line width that differs depending on a position in the plane of the pixel section, the pixel section including the plurality of pixels disposed in a matrix.

The present application claims the benefit of Japanese Priority Patent Application JP2021-171661 filed with the Japan Patent Office on Oct. 20, 2021, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. An imaging device comprising:
a semiconductor substrate having a first surface and a second surface opposed to each other, the semiconductor substrate including a plurality of pixels disposed in a matrix, and a plurality of photoelectric converters that each generates, through photoelectric conversion, electric charge corresponding to an amount of received light for each of the pixels;
a plurality of color filters provided on a side of the first surface in respective ones of the plurality of pixels;
a plurality of condensing lenses provided on a light incident side of the plurality of color filters in the respective ones of the plurality of pixels; and
a separation wall provided between the plurality of color filters adjacent to each other on the side of the first surface, the separation wall having a line width on the light incident side narrower than the line width of the separation wall on the side of the first surface.

2. The imaging device according to claim 1, wherein the separation wall includes a first wall that penetrates the plurality of color filters, and a second wall that protrudes into the condensing lenses.

3. The imaging device according to claim 2, wherein at least a line width of the second wall of the separation wall narrows toward the light incident side.

4. The imaging device according to claim 1, wherein the line width of the separation wall continuously varies from the side of the first surface toward the light incident side.

5. The imaging device according to claim 1, wherein the line width of the separation wall varies stepwise from the side of the first surface toward the light incident side.

6. The imaging device according to claim 2, wherein the second wall penetrates the plurality of condensing lenses.

7. The imaging device according to claim 1, wherein a height of the separation wall substantially coincides with a surface shape of the plurality of condensing lenses in a plane of a pixel section, the pixel section including the plurality of pixels disposed in a matrix.

8. The imaging device according to claim 1, wherein a height of the separation wall differs depending on a position in a plane of a pixel section, the pixel section including the plurality of pixels disposed in a matrix.

9. The imaging device according to claim 8, wherein the height of the separation wall increases from a center of the pixel section toward a periphery of the pixel section.

10. The imaging device according to claim 1, wherein the line width of the separation wall differs depending on a position in a plane of a pixel section, the pixel section including the plurality of pixels disposed in a matrix.

11. The imaging device according to claim 10, wherein the line width of the separation wall narrows from a center of the pixel section toward a periphery of the pixel section.

12. The imaging device according to claim 1, wherein a position where the separation wall is formed differs depending on a position in a plane of a pixel section, the pixel section including the plurality of pixels disposed in a matrix.

13. The imaging device according to claim 12, wherein
the separation wall includes a first wall that penetrates the plurality of color filters and a second wall that protrudes into the condensing lenses, and
the second wall is formed at a position shifted from a center of the pixel section toward a periphery of the pixel section, and from between the plurality of pixels adjacent to each other in a direction of the periphery.

14. The imaging device according to claim 12, wherein an entirety of the separation wall is formed at a position shifted from a center of the pixel section toward a periphery of the pixel section, and from between the plurality of pixels adjacent to each other in a direction of the periphery.

15. The imaging device according to claim 1, wherein the separation wall includes a material having a refractive index lower than the plurality of condensing lenses, or a metal material that absorbs incident light.

16. The imaging device according to claim 1, wherein
the plurality of color filters includes a resin material, and
the plurality of condensing lenses includes one of a resin material having a refractive index of 1.5 or more and 2.0 or less, silicon nitride, silicon oxynitride, silicon oxide, or amorphous silicon.

17. The imaging device according to claim 1, further comprising a light-blocking section provided between the first surface and the separation wall.

18. The imaging device according to claim 17, wherein the light-blocking section is provided in a lattice pattern in a plane of a pixel section, the pixel section including the plurality of pixels disposed in a matrix, and a line width of the light-blocking section differs depending on a position in the plane of the pixel section.

19. The imaging device according to claim 18, wherein the line width of the light-blocking section narrows from a center of the pixel section toward a periphery of the pixel section.

20. The imaging device according to claim 19, wherein the light-blocking section is formed at a position shifted from between the plurality of pixels adjacent to each other toward the center of the pixel section as being closer to the periphery of the pixel section.

21. The imaging device according to claim 1, wherein the plurality of condensing lenses is disposed in a gapless manner.

22. The imaging device according to claim 1, further comprising an element separator provided between the plurality of pixels adjacent to each other, the element separator extending from the first surface toward the second surface of the semiconductor substrate.

23. The imaging device according to claim 22, wherein
the element separator is provided in a lattice pattern in a plane of a pixel section, the pixel section including the plurality of pixels disposed in a matrix, and
the separation wall is formed above the element separator.

24. The imaging device according to claim 23, wherein the line width of the separation wall is equal to or less than a line width of the element separator.

25. The imaging device according to claim 1, wherein the semiconductor substrate includes an uneven structure on the first surface in each of the plurality of pixels.
